(19) United States
(12) Patent Application Publication
(10) Pub. No.: US 2026/0164634 A1
(43) Pub. Date: Jun. 11, 2026

(54) VERTICAL CHANNEL SRAM CELL, METHOD OF MANUFACTURING VERTICAL CHANNEL SRAM CELL, MEMORY, AND ELECTRONIC DEVICE

(71) Applicant: INSTITUTE OF MICROELECTRONICS, CHINESE ACADEMY OF SCIENCES, Beijing (CN)

(72) Inventors: Yongkui ZHANG, Beijing (CN); Xiaolei WANG, Beijing (CN); Jun LUO, Beijing (CN)

(21) Appl. No.: 19/084,068

(22) Filed: Mar. 19, 2025

(30) Foreign Application Priority Data
Dec. 6, 2024 (CN) 202411795167.1

(51) Int. Cl. H10B 10/00

(52) U.S. Cl. CPC H10B 10/125

(57) ABSTRACT

The present disclosure relates to a vertical channel SRAM cell, a method of manufacturing the same, a memory, and an electronic device, which pertain to a field of semiconductor technology. The vertical channel SRAM cell includes: a pull-up transistor device layer; an intermediate spacer layer on the pull-up transistor device layer; and a pull-down transistor device layer separated from the pull-up transistor device layer by the intermediate spacer layer, where the pull-down transistor device layer includes a pull-down transistor and a pass gate transistor; where the pass gate transistor is connected with the pull-down transistor by an upper source layer at identical height; the first pull-up transistor and the first pull-down transistor form a first inverter, the second pull-up transistor and the second pull-down transistor form a second inverter, and the first inverter and the second inverter are coupled to each other through a metal gate strip.

### CROSS REFERENCE TO RELATED APPLICATION

This application claims priority to Chinese Patent Application No. 202411795167.1, filed on Dec. 6, 2024, the entire content of which is incorporated herein in its entirety by reference.

### TECHNICAL FIELD

The present disclosure relates to a field of semiconductor technology, and in particular to a vertical channel SRAM cell, a method of manufacturing a vertical channel SRAM cell, a memory, and an electronic device.

### BACKGROUND

V-GAAFET (Vertical Gate-All-Around Field-Effect Transistor) is a vertically structured gate-all-around field-effect-transistor. Such transistor has a low parasitic capacitance and may achieve better read and write stability because GAAFET has better performance in current control and leakage current suppression. GAAFET has a gate electrode completely surrounding a channel, which may control a flow of electrons more comprehensively and help improve a mobility of electrons, thereby enhancing the performance of transistor.

However, V-GAAFET has a complex structure and is difficult to manufacture.

### SUMMARY

In an aspect, the embodiments of the present disclosure provide a vertical channel SRAM cell, including: a pull-up transistor device layer including a pull-up transistor; an intermediate spacer layer on the pull-up transistor device layer; and a pull-down transistor device layer separated from the pull-up transistor device layer by the intermediate spacer layer, where the pull-down transistor device layer includes a pull-down transistor and a pass gate transistor, the pull-up transistor includes a first pull-up transistor and a second pull-up transistor, the pull-down transistor includes a first pull-down transistor and a second pull-down transistor, and the pass gate transistor includes a first pass gate transistor and a second pass gate transistor; where the pass gate transistor is connected with the pull-down transistor by an upper source layer at identical height; and where the first pull-up transistor and the first pull-down transistor form a first inverter, the second pull-up transistor and the second pull-down transistor form a second inverter, and the first inverter and the second inverter are coupled to each other through a metal gate strip.

Based on a further improvement of the above device, the vertical channel SRAM cell further includes: a wafer substrate; an N well on the wafer substrate; a rectangular ring structure including a plurality of stacked structures on the N well, where a first long side of the rectangular ring includes the first pull-up transistor, the first pull-down transistor and the first pass gate transistor, and a second long side of the rectangular ring includes the second pull-up transistor, the second pull-down transistor and the second pass gate transistor; an insulation layer, located on the rectangular ring structure and an inner cavity of the rectangular ring structure, where the pull-up transistor device layer includes a lower drain layer, a lower channel layer on the lower drain layer, a lower metal gate electrode horizontally surrounding the lower channel layer, and a lower source layer on the lower channel layer and the lower metal gate electrode; the pull-down transistor device layer includes an upper source layer on the intermediate spacer layer, an upper channel layer on the upper source layer, an upper metal gate electrode horizontally surrounding the upper channel layer, and an upper drain layer on the upper channel layer and the upper metal gate electrode; and the intermediate spacer layer is located between the lower source layer and the upper source layer; and a trench passing through the upper drain layer, the upper channel layer and the upper metal gate electrode to expose a top surface of the upper source layer, so as to separate a drain electrode, a channel and a metal gate electrode of the pull-down transistor from a drain electrode, a channel and a metal gate electrode of the pass gate transistor; where the lower drain layers of the pull-up transistors on the two long sides are connected by short sides of the rectangular ring.

Based on a further improvement of the above device, a structure on the first long side is central symmetrical to a structure on the second long side with respect to a center of gravity of the rectangular ring, and the first long side and the second long side are both divided into a first portion and a second portion having the same length; the first portion includes a first step exposing the upper source layer, a second step exposing the lower source layer and a portion of the intermediate spacer layer, and a third step exposing the lower drain layer; a metal gate connector is located on a partial top surface of the first step, a partial top surface of the second step, and a sidewall between the first step and the second step, so that the upper source layer and the lower source layer are connected through the metal gate connector; and the second portion includes the trench as well as a first protruding portion and a second protruding portion that sandwich the trench, and the first protruding portion is adjacent to the first step.

Based on a further improvement of the above device, the metal gate strip includes a first metal gate strip and a second metal gate strip, and the vertical channel SRAM cell further includes: a first power contact passing through the insulation layer to reach a top surface of the third step; a second power contact passing through the insulation layer to reach a top surface of the first protruding portion; a bit line contact passing through the insulation layer to reach a top surface of the second protruding portion; a word line contact passing through the insulation layer to reach the upper metal gate electrode on the top surface of the second protruding portion; the first metal gate strip configured to connect the second step on the first long side with the first protruding portion on the second long side; and the second metal gate strip configured to connect the first protruding portion on the first long side with the second step on the second long side.

In another aspect, the embodiments of the present disclosure provide a method of manufacturing a vertical channel SRAM cell, including: forming an N well on a wafer substrate; forming a plurality of stacked structures on the N well, and forming the plurality of stacked structures into a rectangular ring structure, where the plurality of stacked structures include a pull-up transistor device layer, an intermediate spacer and a pull-down transistor device layer from bottom to top, and the pull-up transistor device layer and the pull-down transistor device layer both include a lower semiconductor layer, a channel layer on the lower semiconductor layer, and an upper semiconductor layer on the channel layer; forming the upper semiconductor layer and the lower semiconductor layer in the pull-down transistor device layer on two long sides of the rectangular ring structure into an upper drain electrode and an upper source electrode respectively; forming two trenches as well as first protruding portions and second protruding portions that sandwich the two trenches on the two long sides of the rectangular ring structure in a centrally symmetrical manner, where the two trenches pass through an upper drain layer and an upper channel layer in the pull-down transistor device layer to separate a drain region and a channel region of a pull-down transistor from a drain region and a channel region of a pass gate transistor on each long side; forming a first step, a second step and a third step at a remaining portion of the two long sides, where the first step exposes the lower semiconductor layer in the pull-down transistor device layer, the second step exposes the upper semiconductor layer in the pull-up transistor device layer and a portion of the intermediate spacer, the third step exposes the lower semiconductor layer in the pull-up transistor device layer, and the first step is adjacent to the first protruding portion; forming metal gate electrodes of transistors at an inner end portion and an outer end portion of the upper channel layer and an inner end portion and an outer end portion of the lower channel layer in the rectangular ring structure, and forming a first metal gate electrode and a second metal gate electrode, where the first metal gate electrode connects the second step on the first long side with the first protruding portion on the second long side, and the second metal gate electrode connects the first protruding portion on the first long side with the second step on the second long side; and forming a plurality of contacts on the rectangular ring structure to connect to the third step, the first protruding portion, the second protruding portion, and the metal gate electrode of the pass gate transistor, respectively.

Based on a further improvement of the above method, the forming a plurality of stacked structures on the N well includes: forming a pull-up transistor device layer on the N well; forming a spacer semiconductor layer on the pull-up transistor device layer; and forming a pull-down transistor device layer on the spacer semiconductor layer, where the pull-up transistor device layer and the pull-down transistor device layer both include a lower semiconductor layer, an intermediate semiconductor layer on the lower semiconductor layer, and an upper semiconductor layer on the intermediate semiconductor layer, where the lower semiconductor layer and the upper semiconductor layer of the pull-down transistor device layer are respectively the upper source layer and the upper drain layer, the lower semiconductor layer and the upper semiconductor layer of the pull-up transistor device layer are respectively the lower drain layer and the lower source layer, and the upper source layer, the upper drain layer, the lower drain layer and the lower source layer are made of silicon; and where the intermediate semiconductor layer in the pull-down transistor device layer is a top intermediate semiconductor layer, the intermediate semiconductor layer in the pull-up transistor device layer is a bottom intermediate semiconductor layer, and the top intermediate semiconductor layer, the bottom intermediate semiconductor layer and the spacer semiconductor layer are made of germanium silicon.

Based on a further improvement of the above method, the forming the plurality of stacked structures into a rectangular ring structure includes: forming a first oxide layer, an amorphous silicon layer and a second oxide layer sequentially on the upper drain layer in the pull-down transistor device layer; performing a reactive ion etching process on the second oxide layer, the amorphous silicon layer and the first oxide layer by using a patterned photoresist layer as a mask, where the patterned photoresist layer has the same size as an inner ring of the rectangular ring structure in a vertical direction; conformally depositing a third oxide layer on the upper drain layer and the etched second oxide layer; performing a reactive ion etching process on the third oxide layer to form a spacer on an outer wall of the second oxide layer, an outer wall of the amorphous silicon layer and an outer wall of the first oxide layer; etching the plurality of stacked structures into an outer rectangle of the rectangular ring by using the spacer as a mask, and stopping at a portion of the lower drain layer in the pull-up transistor device layer, so as to form an upper outer lateral gap having a first width at the outer end portion of the top intermediate semiconductor layer, a lower outer lateral gap having the first width at the outer end portion of the bottom intermediate semiconductor layer, and an intermediate outer lateral gap having a second width at the outer end portion of the spacer semiconductor layer, where the second width is greater than the first width; forming an intermediate spacer having a third width in the intermediate outer lateral gap, and forming the upper channel layer having a fourth width in the upper outer lateral gap and the lower channel layer having the fourth width in the lower outer lateral gap to maintain a remaining upper outer lateral gap and a remaining lower outer lateral gap, where the third width is less than the second width, and the fourth width is less than the first width; performing a chemical mechanical polishing process on the second oxide layer, and stopping at the amorphous silicon layer; performing a wet etching process on the exposed amorphous silicon layer, continuing to perform a reactive ion etching process on the plurality of stacked structures and stopping at a portion of the lower drain layer in the pull-up transistor device layer, so as to form the rectangular ring structure as a nanosheet and an inner cavity surrounded by the nanosheet; and performing a selective reactive ion etching process on the upper channel layer, the spacer semiconductor layer and the lower channel layer in the inner cavity relative to the upper drain layer, the upper source layer, the lower source layer and the lower drain layer, so as to form an upper inner lateral gap having a fifth width at the inner end portion of the upper channel layer, a lower inner lateral gap having the fifth width at the inner end portion of the lower channel layer, and an intermediate inner lateral gap having a sixth width at the inner end portion of the spacer semiconductor layer, where the fifth width is greater than the sixth width.

Based on a further improvement of the above method, the forming the upper semiconductor layer and the lower semiconductor layer in the pull-down transistor device layer on the two long sides into an upper drain electrode and an upper source electrode respectively includes: depositing a fourth oxide layer in the inner cavity, where the upper inner lateral gap, the lower inner lateral gap and the intermediate inner lateral gap are filled with the fourth oxide layer; performing a recess process on a shallow trench isolation oxide and the fourth oxide layer and stopping at a bottom surface of the upper source layer, so as to restore the remaining upper outer lateral gap and the upper inner lateral gap; conformally depositing a fifth oxide layer and a silicon nitride layer in the remaining upper outer lateral gap and the upper inner lateral gap, and performing a selective etching process on the fifth oxide layer and the silicon nitride layer to form an upper outer spacer and an upper inner spacer; and performing a drain/source implantation process on the upper drain layer and the upper source layer by using the upper outer spacer and the upper inner spacer as masks, so as to form a drain/source implanted upper drain layer and a drain/source implanted upper source layer.

Based on a further improvement of the above method, the forming two trenches as well as first protruding portions and second protruding portions that sandwich the two trenches on the two long sides of the rectangular ring structure in a centrally symmetrical manner includes: removing the upper outer spacer and the upper inner spacer to restore the remaining upper outer lateral gap and the upper inner lateral gap to expose the upper channel layer; and performing a photolithography and a fin etching process on the drain/source implanted rectangular ring structure, so as to remove the drain/source implanted upper drain layer and the upper channel layer on the two short sides, a right half of the first long side and a left half of the second long side, and form a first trench and a second trench on a left half of the first long side and a right half of the second long side respectively, where the first trench and the second trench respectively expose a top surface of the upper source layer on the first long side and a top surface of the upper source layer on the second long side; where the first trench is sandwiched between the first protruding portion and the second protruding portion on the first long side, and the second trench is sandwiched between the first protruding portion and the second protruding portion on the second long side; and where the first trench has the same width as the second trench, the first protruding portion on the first long side has the same width as the first protruding portion on the second long side, and the second protruding portion on the first long side has the same width as the second protruding portion on the second long side.

Based on a further improvement of the above method, the forming a first step, a second step and a third step at a remaining portion of the two long sides includes: continuing to perform a recess process on the shallow trench isolation oxide and the fifth oxide layer until reaching the lower source layer in the pull-up transistor device layer, so as to restore the intermediate outer lateral gap having the third width and the intermediate inner lateral gap; performing a photolithography and a fin etching process on the two short sides, the first portion in the right half of the first long side and the first portion in the left half of the second long side, while leaving the first step on the first long side and the first step on the second long side unetched, where the first step on the first long side and the first step on the second long side have the same width as the first protruding portion; continuing to perform a recess process on the shallow trench isolation oxide and the fifth oxide layer until reaching the lower drain layer in the pull-up transistor device layer, so as to restore the remaining lower outer lateral gap and the lower inner lateral gap to expose the lower channel layer; performing a photolithography and a fin etching process on the two short sides, a portion of the first portion on the first long side and a portion of the first portion on the second long side, so as to form the third step on the first long side and the third step on the second long side and leave the second step on the first long side and the second step on the second long side unetched.

Based on a further improvement of the above method, the forming metal gate electrodes of transistors at an inner end portion and an outer end portion of the upper channel layer and an inner end portion and an outer end portion of the lower channel layer in the rectangular ring structure includes: conformally depositing a high-K dielectric layer and a p-type work function metal layer on the wafer substrate; depositing a sixth oxide layer on the p-type work function metal layer and performing a chemical mechanical polishing process on the sixth oxide layer; performing a recess process on the sixth oxide layer to expose the pull-down transistor device layer; etching the exposed p-type work function metal layer, and depositing an n-type work function metal layer on the exposed high-K dielectric layer; depositing a seventh oxide layer on the n-type work function metal layer, and etching a portion of the seventh oxide layer and a portion of the n-type work function metal layer to form oxide spacers in the upper inner lateral gap and the lower inner lateral gap; performing a recess process on the remaining oxide layer until reaching the p-type work function metal layer, and then depositing a tungsten metal layer; and performing a photolithography and an anisotropic etching process on the tungsten metal layer and the p-type work function metal layer until reaching the high-K dielectric layer, so as to form metal gate electrodes of the pull-down transistor and the pass gate transistor at the inner end portion and the outer end portion of the upper channel layer and form a metal gate electrode of the pull-up transistor at the inner end portion and the outer end portion of the lower channel layer.

In the present disclosure, the above-mentioned technical solutions may be combined with each other to achieve more preferred combined solutions. Other features and advantages of the present disclosure will be described in the following specification, and some advantages may become apparent from the specification or be learned by practicing the present disclosure. The objectives and other advantages of the present disclosure may be achieved and obtained through contents specifically indicated in the specification and the accompanying drawings.

### BRIEF DESCRIPTION OF THE DRAWINGS

This application contains at least one drawing executed in color. Copies of this patent application with color drawings will be provided by the Office upon request and payment of the necessary fee.

The accompanying drawings are merely for the purpose of illustrating specific embodiments and should not be understood as limitations to the present disclosure. Throughout the accompanying drawings, the same reference numerals represent the same components.

FIG. 1 to FIG. 18 and FIG. 1A to FIG. 18A respectively show top views and cross-sectional views taken along line A-A′ in various processes of manufacturing a vertical channel SRAM cell according to an embodiment of the present disclosure;

FIG. 19 to FIG. 24, FIG. 19A to FIG. 24A, FIG. 19B to FIG. 24B, FIG. 19C to FIG. 24C, FIG. 19D to FIG. 24D, FIG. 21E to FIG. 22E and FIG. 24E respectively show top views and cross-sectional views taken along line A-A′, line B-B′, line C-C′, line D-D′ and line E-E′ in various processes of manufacturing a vertical channel SRAM cell according to an embodiment of the present disclosure;

FIG. 25 to FIG. 28, FIG. 25B to FIG. 28B, FIG. 25C to FIG. 28C, FIG. 25D to FIG. 28D and FIG. 25E to FIG. 28E respectively show top views and cross-sectional views taken along line B-B′, line C-C′, line D-D′ and line E-E′ in various processes of manufacturing a vertical channel SRAM cell according to an embodiment of the present disclosure;

FIG. 29 to FIG. 32, FIG. 29A to FIG. 32A, FIG. 29B to FIG. 32B, FIG. 29C to FIG. 32C, FIG. 29D to FIG. 32D, FIG. 29E to FIG. 32E and FIG. 29F to FIG. 32F respectively show top views and cross-sectional views taken along line A-A′, line B-B′, line C-C′, line D-D′, line E-E′ and line F-F′ in various processes of manufacturing a vertical channel SRAM cell according to an embodiment of the present disclosure;

FIG. 33 to FIG. 36, FIG. 33B to FIG. 36B, FIG. 33C to FIG. 36C, FIG. 33D to FIG. 36D, FIG. 33E to FIG. 36E and FIG. 33F to FIG. 36F respectively show top views and cross-sectional views taken along line B-B′, line C-C′, line D-D′, line E-E′ and line F-F′ in various processes of manufacturing a vertical channel SRAM cell according to an embodiment of the present disclosure;

FIG. 37 and FIG. 37B respectively show a top view and a cross-sectional view taken along line B-B′ of a vertical channel SRAM cell according to an embodiment of the present disclosure; and

FIG. 38 shows a schematic diagram of a vertical channel SRAM cell according to an embodiment of the present disclosure.

### REFERENCE NUMERALS

101—wafer substrate; 102—N well; 103—first lower semiconductor layer; 104—first intermediate semiconductor layer; 105—first upper semiconductor layer; 106—spacer semiconductor layer; 107—second lower semiconductor layer; 108—second intermediate semiconductor layer; 109—second upper semiconductor layer; 110—oxide layer; 111—amorphous silicon layer; 112—oxide layer; 113—spacer; 114—lower lateral gap; 115—intermediate lateral gap; 116—upper lateral gap; 117—lower spacer; 118—intermediate spacer; 119—upper spacer; 120—partial intermediate lateral gap; 121—remaining intermediate spacer; 122—lower channel layer; 123—upper channel layer; 124—peripheral region; 125—active region; 126—shallow trench isolation; 127—first cavity; 128—second cavity; 129—lower inner lateral gap; 130—intermediate inner lateral gap; 131—upper inner lateral gap; 132—oxide layer; 133—third cavity; 134—upper inner lateral gap; 135—upper outer lateral gap; 136—upper inner spacer; 137—upper outer spacer; 138—first trench; 139—second trench; 140—first protruding portion; 141—second protruding portion; 142—right half of first long side; 143—first short side; 144—first protruding portion; 145—second protruding portion; 146—left half of second long side; 147—second short side; 148—fourth cavity; 149—recessed portion; 150—first portion on right half of first long side; 151—first step on right half of first long side; 152—first portion on left half of second long side; 153—first step on left half of second long side; 154—fifth cavity; 155—recessed portion; 156—third step on right half of first long side; 157—third step on left half of second long side; 158—second step on right half of first long side; 159—second step on left half of second long side; 160—high-K dielectric layer (HK); 161—p-type work function metal layer (p WFM); 162—oxide layer; 163—n-type work function metal layer (n WFM); 164—oxide spacer; 165—tungsten metal layer; 166—first high-K metal gate electrode; 167—second high-K metal gate electrode; 168—third high-K metal gate electrode; 169—fourth high-K metal gate electrode; 170—bottom oxide layer; 171—intermediate amorphous silicon layer; 172—top oxide layer; 173—oxide layer; 3701—wafer substrate; 3702—N well; 3703—lower drain layer; 3704—lower channel layer; 3705—lower source layer; 3706—intermediate spacer; 3707—upper source layer; 3708—upper channel layer; 3709—upper drain layer; 3710—lower metal gate electrode; 3711—upper metal gate electrode; 3712—trench; 3713—third step; 3714—second step; 3715—first step; 3716—first protruding portion; 3717—second protruding portion; 3718—insulation layer.

### DETAILED DESCRIPTION OF EMBODIMENTS

Preferred embodiments of the present disclosure will be described in detail below with reference to the accompanying drawings. The accompanying drawings constitute a part of the present disclosure and are used together with the embodiments of the present disclosure to illustrate principles of the present disclosure, and are not intended to limit the scope of the present disclosure.

The embodiments of the present disclosure aim to provide a vertical channel SRAM cell, a method of manufacturing a vertical channel SRAM cell, a memory and an electronic device, in order to solve the problem that existing transistors are difficult to manufacture due to complex structures.

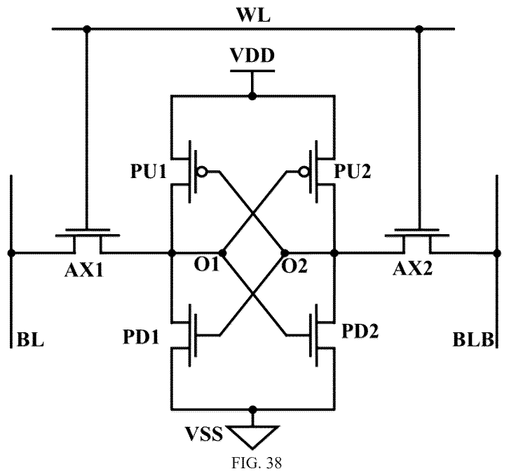

Referring to FIG. 37, FIG. 37B and FIG. 38, a specific embodiment of the present disclosure provides a vertical channel SRAM cell, including a wafer substrate 3701 and an N well 3702 on the wafer substrate 3701.

A rectangular ring structure including a plurality of stacked structures is located on the N well. A first long side of the rectangular ring includes a first pull-up transistor PU1, a first pull-down transistor PD1, and a first pass gate transistor AX1. A second long side of the rectangular ring includes a second pull-up transistor PU2, a second pull-down transistor PD2, and a second pass gate transistor AX2.

Specifically, the plurality of stacked structures include: a pull-up transistor device layer including a pull-up transistor, where the pull-up transistor includes the first pull-up transistor PU1 and the second pull-up transistor PU2; an intermediate spacer layer on the pull-up transistor device layer; and a pull-down transistor device layer separated from the pull-up transistor device layer by the intermediate spacer layer, where the pull-down transistor device layer includes a pull-down transistor and a pass gate transistor, the pull-down transistor includes a first pull-down transistor PD1 and a second pull-down transistor PD2, and the pass gate transistor includes a first pass gate transistor AX1 and a second pass gate transistor AX2. The pass gate transistor is connected with the pull-down transistor by an upper source layer at identical height. The first pull-up transistor PU1 and the first pull-down transistor PD1 form a first inverter, and the second pull-up transistor PU2 and the second pull-down transistor PD2 form a second inverter. The first inverter and the second inverter are coupled to each other through a metal gate strip.

The above technical solution has the following beneficial effects. The vertical channel SRAM cell includes a plurality of vertically structured gate-all-around field-effect-transistors, and a structure of each memory cell has a compact layout by forming a pull-up transistor in the pull-up transistor layer and forming a pull-down transistor and a pass gate transistor in the pull-down transistor layer on each side of the rectangular ring.

An insulation layer 3718 is provided on the rectangular ring structure and an inner cavity of the rectangular ring structure. In addition, the wafer substrate includes a peripheral region around the rectangular ring and an active region surrounded by the peripheral region. The rectangular ring structure is provided in the active region.

A plurality of interactive stacked layers include a lower drain layer 3703, a lower channel layer 3704, a lower source layer 3705, an intermediate spacer 3706, an upper source layer 3707, an upper channel layer 3708 and an upper drain layer 3709 from bottom to top. The lower drain layer 3703, the lower channel layer 3704, the lower source layer 3705, the upper source layer 3707, the upper channel layer 3708 and the upper drain layer 3709 are made of silicon. The intermediate spacer 3706 is made of oxide with a thickness of 5 nm and silicon nitride with a thickness in a range of 10 nm to 100 nm.

The pull-up transistor (i.e., a lower transistor) PU2 (or PU1) includes a lower drain layer 3703, a lower channel layer 3704 on the lower drain layer 3703, a lower metal gate electrode 3710 horizontally surrounding the lower channel layer 3704, and a lower source layer 3705 on the lower channel layer 3704 and the lower metal gate electrode 3710. The lower drain layers 3703 of the pull-up transistors on two long sides are connected through short sides of the rectangular ring.

The pull-down transistor (i.e., an upper transistor) PD2 (or PD1) and the pass gate transistor AX2 (or AX1) include an upper source layer 3707 on the intermediate spacer 3706, an upper channel layer 3708 on the upper source layer, an upper metal gate electrode 3711 horizontally surrounding the upper channel layer 3708, and an upper drain layer 3709 on the upper channel layer 3708 and the upper metal gate electrode 3711. The intermediate spacer 3706 is located between the lower source layer 3705 and the upper source layer 3707.

The rectangular ring includes a first long side and a second long side, and a structure on the first long side is central symmetrical with a structure on the second long side with respect to a center of gravity of the rectangular ring. The first long side and the second long side are both divided into a first portion and a second portion, which have the same length. Specifically, the first portion refers to a right half of the first long side and a left half of the second long side, and the second portion refers to a left half of the first long side and a right half of the second long side.

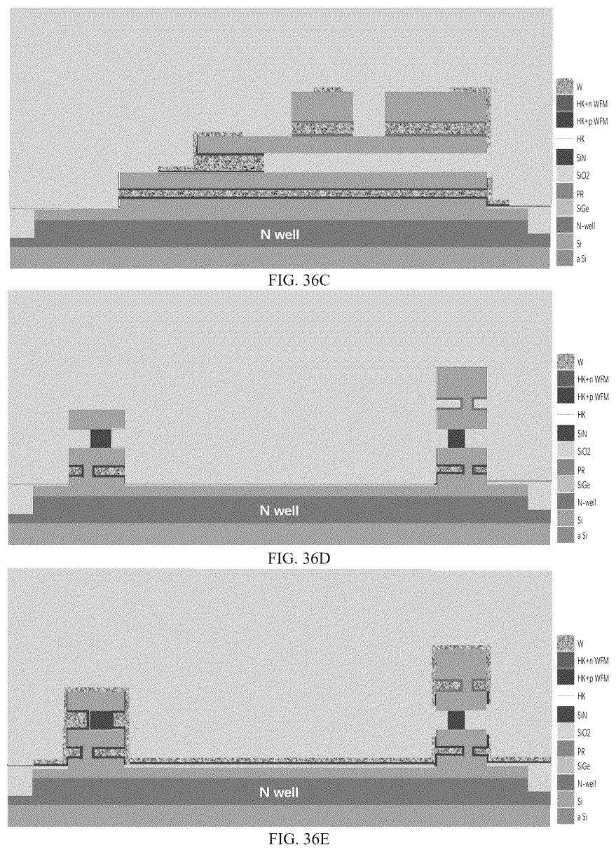

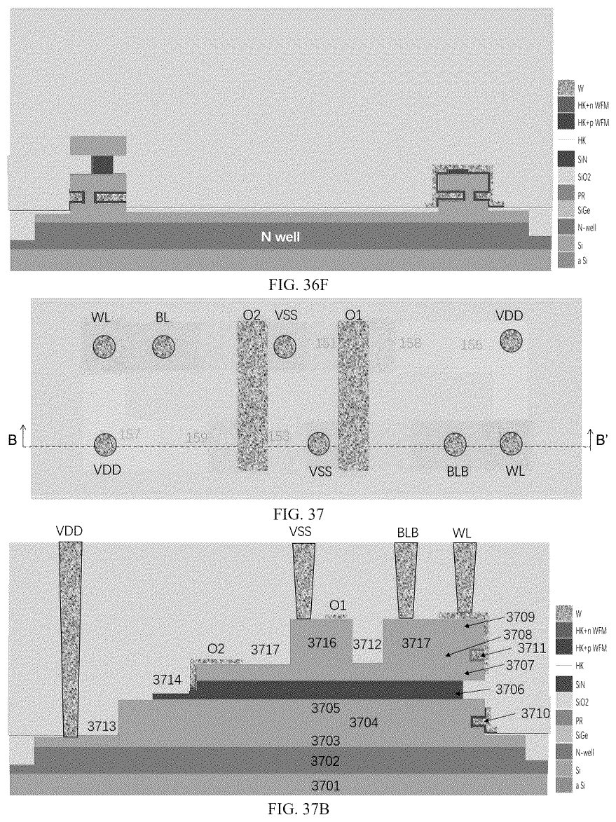

The first portion includes a first step 3715, a second step 3714, and a third step 3713. The first step 3715 exposes the upper source layer 3707, the second step 3714 exposes the lower source layer 3705 and a portion of the intermediate spacer 3706, and the third step 3713 exposes the lower drain layer. A metal gate connector is located on a partial top surface of the first step 3715, a partial top surface of the second step 3714, and a sidewall between the first step 3715 and the second step 3714, so that the upper source layer 3707 and the lower source layer 3705 are connected through the metal gate connector (referring to FIG. 36C).

The second portion includes a trench 3712 as well as a first protruding portion 3716 and a second protruding portion 3717 that sandwich the trench 3712. The first protruding portion 3716 is adjacent to the first step 3715. The trench 3712 passes through the upper drain layer 3709, the upper channel layer 3708 and the upper metal gate electrode 3711 to expose a top surface of the upper source layer 3707, thereby separating the drain electrode, the channel and the metal gate electrode of the pull-down transistor from the drain electrode, the channel and the metal gate electrode of the pass gate transistor. The right half of the second long side includes the trench 3712 as well as the first protruding portion 3716 and the second protruding portion 3717 that sandwich the trench 3712. For specific details about the trench and the first step to the third step on the first long side, reference may be made to FIG. 36 and FIG. 36B to FIG. 36F.

In addition, each memory cell includes: a first power contact VDD passing through the insulation layer 3718 to reach a top surface of the third step 3713; a second power contact VSS passing through the insulation layer 3718 to reach a top surface of the first protruding portion 3716; a bit line contact BLB passing through the insulation layer 3718 to reach a top surface of the second protruding portion 3717; a word line contact WL passing through the insulation layer 3718 to reach the upper metal gate electrode 3711 on the top surface of the second protruding portion 3717; a first metal gate strip O1 used to connect the second step on the first long side with the first protruding portion 3716 on the second long side; and a second metal gate strip O2 used to connect the first protruding portion on the first long side with the first step 3715 on the second long side.

Another specific embodiment of the present disclosure provides a method of manufacturing a vertical channel SRAM cell, including the following steps.

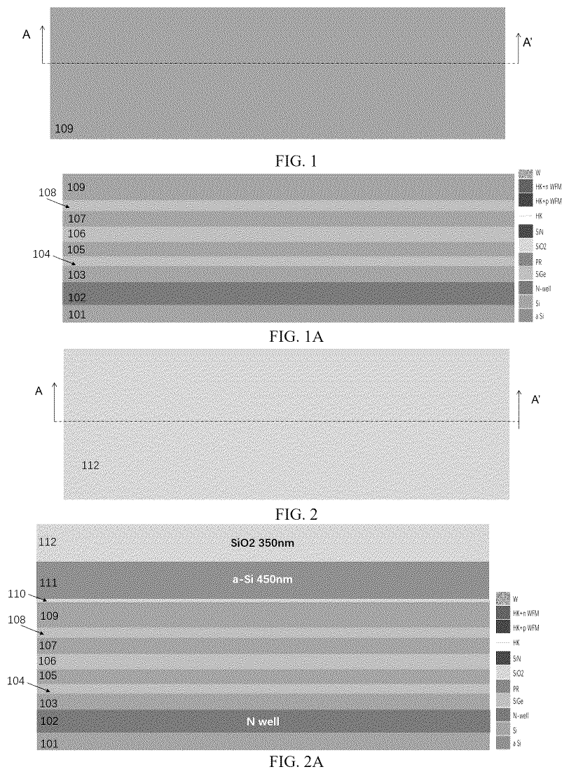

Referring to FIG. 1 and FIG. 1A, in step S3901, an N well 102 is formed on a wafer substrate 101. Specifically, an oxide layer is deposited on the wafer substrate 101, and an ion implantation (IMP) process and an annealing process are performed on the wafer substrate to form the N well 102. Then, the oxide layer is removed to expose the N well 102. The wafer substrate is made of Si.

Referring to FIG. 1 to FIG. 13A, in step S3902, a plurality of stacked structures are formed on the N well 102, and then the plurality of stacked structures are formed into a rectangular ring structure. The plurality of stacked structures include a pull-up transistor device layer, an intermediate spacer and a pull-down transistor device layer from bottom to top. The pull-up transistor device layer and the pull-down transistor device layer include a lower semiconductor layer, a channel layer on the lower semiconductor layer, and an upper semiconductor layer on the channel layer. This step will be described in detail below.

Referring to FIG. 1 and FIG. 1A, the plurality of stacked structures are epitaxially grown on the N well 102. Specifically, a pull-up transistor device layer is formed on the N well, a spacer semiconductor layer is formed on the pull-up transistor device layer, and a pull-down transistor device layer is formed on the spacer semiconductor layer. The pull-up transistor device layer and the pull-down transistor device layer both include a lower semiconductor layer, an intermediate semiconductor layer on the lower semiconductor layer, and an upper semiconductor layer on the intermediate semiconductor layer. Specifically, a first lower semiconductor layer 103, a first intermediate semiconductor layer 104, a first upper semiconductor layer 105, a spacer semiconductor layer 106, a second lower semiconductor layer 107, a second intermediate semiconductor layer 108 and a second upper semiconductor layer 109 are epitaxially grown on the N well 102 sequentially. The first lower semiconductor layer 103 and the first upper semiconductor layer 105 are respectively used as a lower drain layer and a lower source layer of the pull-up transistor device layer, both of which have a thickness of 100 nm and made of silicon doped with phosphorus P. The first intermediate semiconductor layer 104, which is replaced with a lower channel layer in a subsequent manufacturing process, has a thickness of 60 nm and is made of Si_{1-X}Ge_{X}. The second lower semiconductor layer 107 and the second upper semiconductor layer 109 are respectively used as an upper drain layer and an upper source layer of the pull-down transistor device layer, which have thicknesses of 100 nm and 150 nm respectively and are made of intrinsic silicon. The second intermediate semiconductor layer 108, which is replaced with an upper channel layer in the subsequent manufacturing process, is made of Si_{1-X}Ge_{X} and has a thickness of 60 nm. The spacer semiconductor layer 106 is located between the pull-down transistor device layer and the pull-up transistor device layer, and is replaced with an intermediate spacer in the subsequent manufacturing process to separate the pull-down transistor device layer from the pull-up transistor device layer. The spacer semiconductor layer 106 has a thickness of 100 nm and is made of Si_{1-Y}Ge_{Y}, where Y is greater than X, for example, X=1.2 and Y=0.4.

Referring to FIG. 2 and FIG. 2A, an oxide layer 110, an amorphous silicon layer 111 and an oxide layer 112 are sequentially deposited on the plurality of stacked structures. For example, the oxide layer 110, the amorphous silicon layer 111 and the oxide layer 112 are respectively made of SiO₂, amorphous silicon and SiO₂, and respectively have thicknesses of 20 nm, 450 nm and 350 nm.

Referring to FIG. 3 and FIG. 3A, a photoresist (PR) is formed on the oxide layer 112 and patterned into a mandrel pattern. The mandrel pattern is located at a center of the wafer substrate and has the same size as an inner ring of the rectangular ring structure in a vertical direction, which may be, for example, 40 nm×80 nm. The mandrel pattern is used to form the inner ring of the rectangular ring structure in subsequent manufacturing processes. Then, by using the mandrel pattern as a mask, a reactive ion etching (RIE) process is sequentially performed on the oxide layer 112, the amorphous silicon layer 111 and the oxide layer 110 and stops at the second upper semiconductor layer 109 in the plurality of stacked structures, so that the mandrel pattern is transferred to the oxide layer 112, the amorphous silicon layer 111 and the oxide layer 110. Then, the photoresist (i.e., the mandrel pattern) on the patterned oxide layer 112 is removed, while the patterned oxide layer 112, the patterned amorphous silicon layer 111 and the patterned oxide layer 110 are retained.

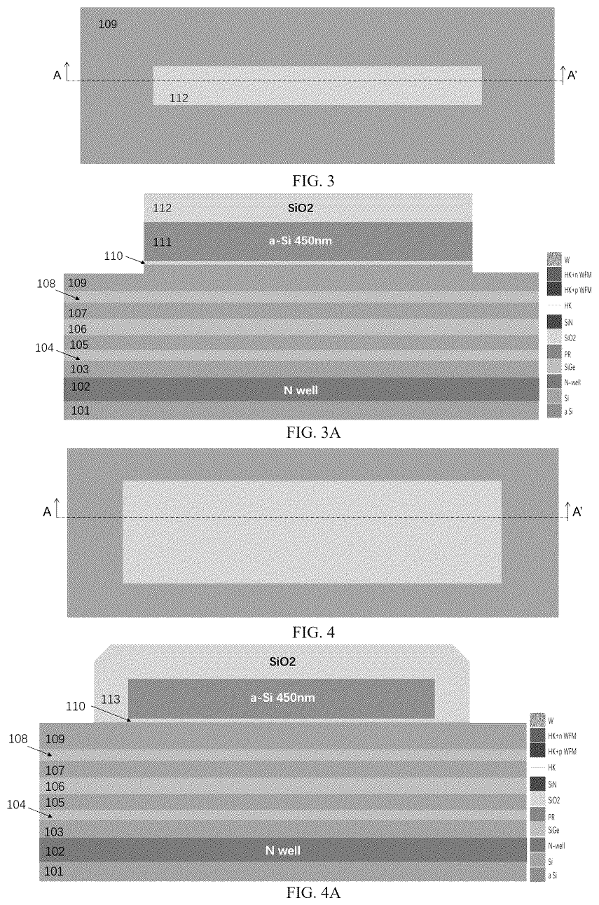

Referring to FIG. 4 and FIG. 4A, an oxide layer (e.g., SiO₂) of 700 angstrom is conformally deposited on the patterned oxide layer 112 and the exposed second upper semiconductor layer 109. Then, a reactive ion etching process is performed on the conformally deposited oxide layer to remove the oxide on the second upper semiconductor layer 109, so that a spacer 113 is formed on an outer sidewall of the patterned oxide layer 112, an outer sidewall of the patterned amorphous silicon layer 111 and an outer sidewall of the patterned oxide layer 110, and the spacer 113 is a rectangular ring. A remaining oxide includes the oxide remaining on the patterned oxide layer 112 as well as the spacer 113 on the outer sidewall of the patterned oxide layer 112, the outer sidewall of the patterned amorphous silicon layer 111 and the outer sidewall of the patterned oxide layer 110.

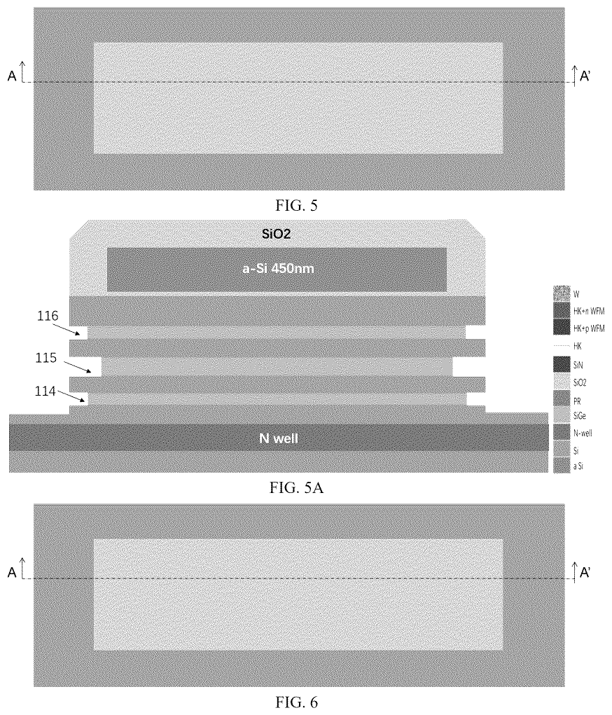

Referring to FIG. 5 and FIG. 5A, by using the spacer 113 as a mask, a selective etching process is performed on the plurality of stacked structures to form an outer rectangle of the rectangular ring, so as to form a lateral gap between adjacent silicon layers and expose a portion of the first lower semiconductor layer 103, where an etching rate of a germanium silicon layer is greater than that of a silicon layer, and an exposed surface of the portion of the first lower semiconductor layer 103 is located between a top surface and a bottom surface of the first lower semiconductor layer 103 in the vertical direction. An etching depth of the SiGe layer is proportional to the thickness of the SiGe layer, that is, the thicker the SiGe layer, the greater the etching depth of the SiGe layer. For example, an intermediate lateral gap (i.e., intermediate outer lateral gap) 115 is formed at an outer end portion of the spacer semiconductor layer 106, a lower lateral gap (i.e., lower outer lateral gap) 114 is formed at an outer end portion of the first intermediate semiconductor layer 104, and an upper lateral gap (i.e., upper outer lateral gap) 116 is formed at an outer end portion of the second intermediate semiconductor layer 108. Specifically, the lower lateral gap 114 and the upper lateral gap 116 have a first width, the intermediate lateral gap 115 has a second width, and the second width is greater than the first width.

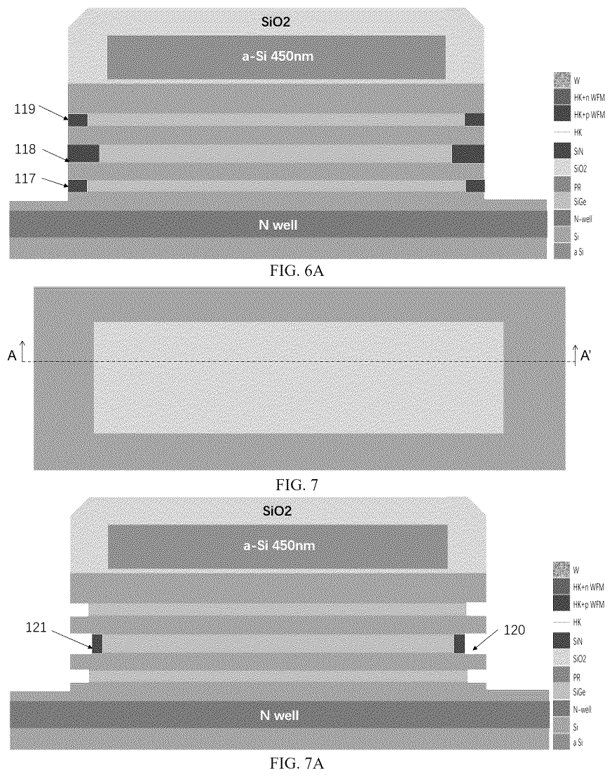

Referring to FIG. 6 and FIG. 6A, an oxide layer, or an oxide layer and a silicon nitride layer, is/are conformally deposited on sidewalls of the plurality of etched stacked structures, and a selective etching process is performed on the silicon nitride layer and the oxide layer to form inner spacers in the lateral gaps. The inner spacers include a lower spacer 117 in the lower lateral gap 114, an intermediate spacer 118 in the intermediate lateral gap 115, and an upper spacer 119 in the upper lateral gap 116. For example, the oxide layer has a thickness of 5 nm, and the silicon nitride layer has a thickness in a range of 10 nm to 100 nm.

Referring to FIG. 7 and FIG. 7A, a selective etching process is performed on the inner spacers to remove the lower spacer 117, a portion of the intermediate spacer, and the upper spacer 119, so as to form an upper lateral gap 116 exposing the upper germanium silicon layer, a partial intermediate lateral gap 120 exposing the remaining intermediate spacer, and a lower lateral gap 114 exposing the lower germanium silicon layer, while retaining a remaining intermediate spacer 121 having a third width, where the third width is less than the second width.

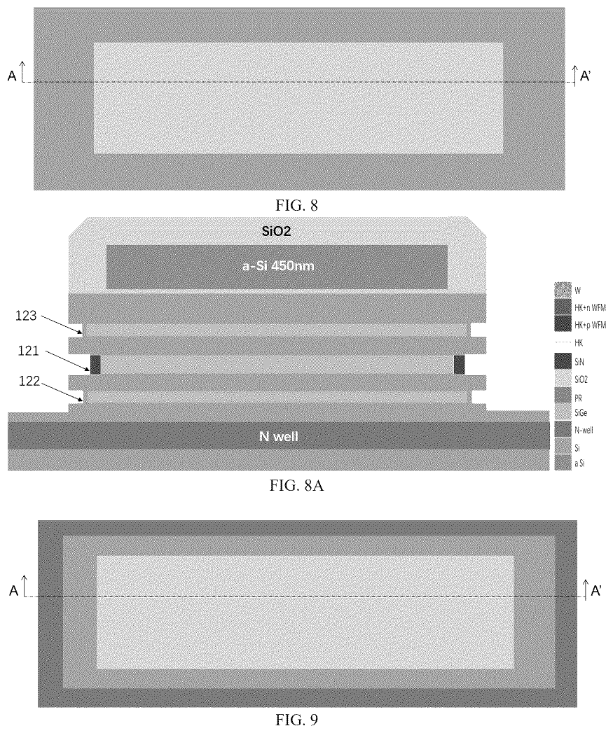

Referring to FIG. 8 and FIG. 8A, a channel material is deposited in the upper lateral gap 116 and the lower lateral gap 114 by using a selective epitaxial process, so as to form an upper channel layer 123 of the pull-down transistor device and a lower channel layer 122 of the pull-up transistor device, where the upper channel layer 123 and the lower channel layer 122 have a fourth width, and the fourth width is less than the first width. The channel material is a Si layer having a width in a range of 5 nm to 20 nm.

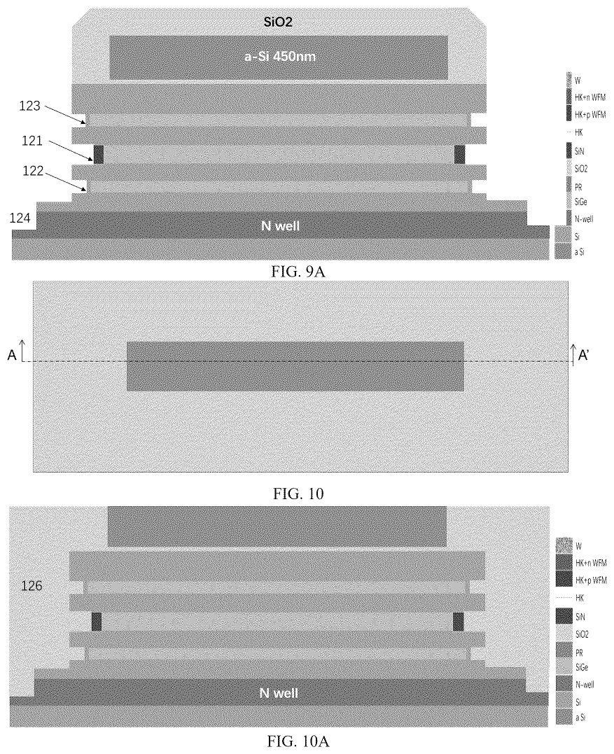

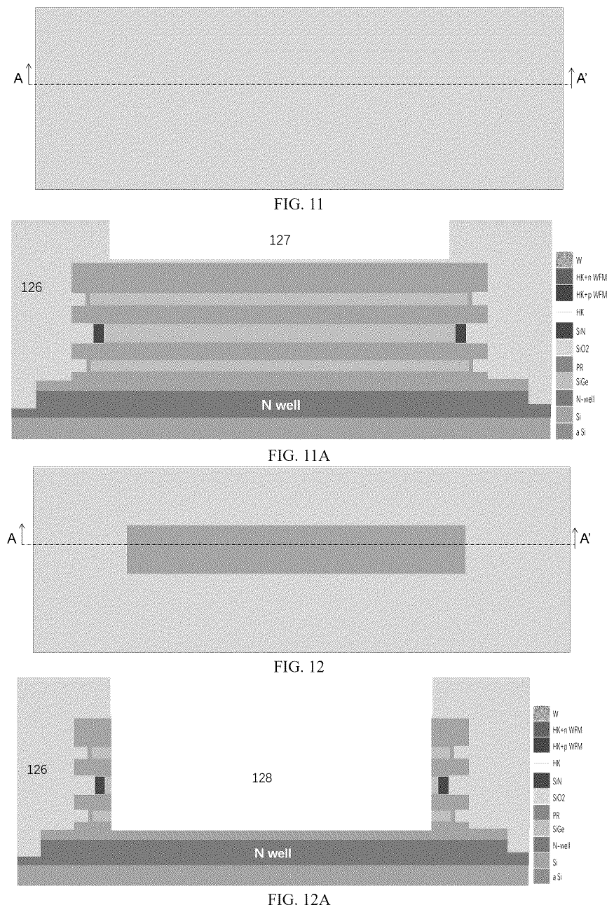

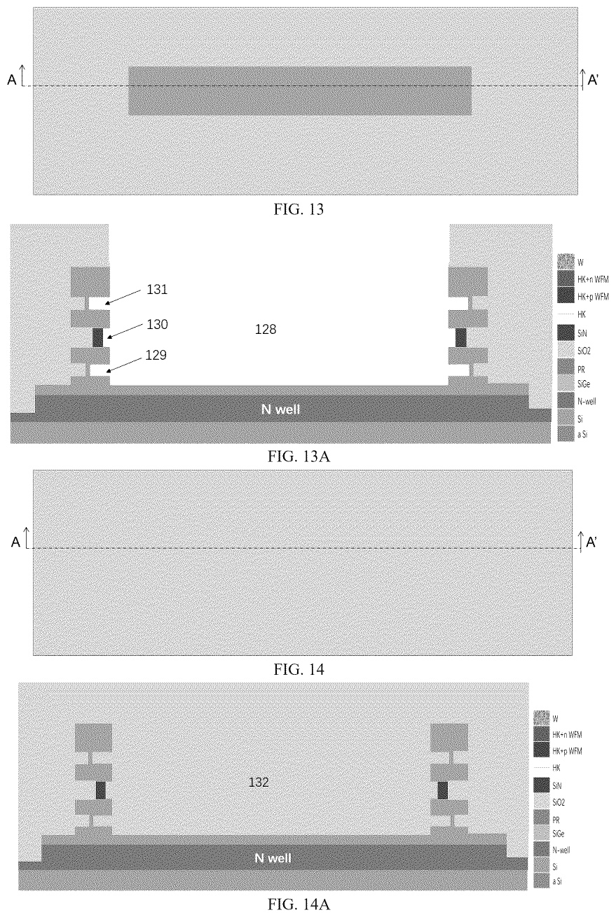

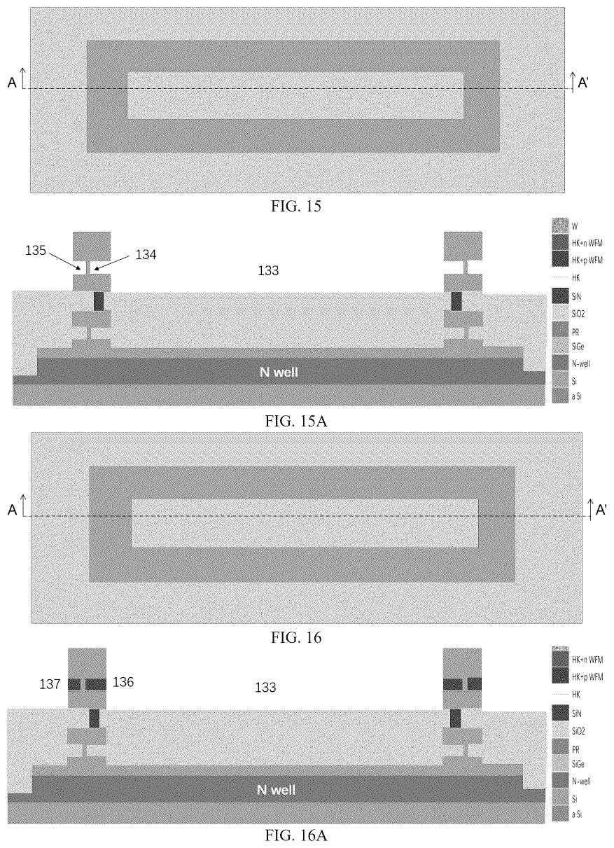

Referring to FIG. 9 and FIG. 9A, a photolithography and an etching process are performed on the exposed lower silicon layer and a portion of the N well to form a peripheral region 124 and an active region 125 surrounding the peripheral region 124.

Referring to FIG. 10 and FIG. 10A, an oxide is deposited on the wafer substrate and a chemical mechanical polishing process is performed on the oxide to form a shallow trench isolation 126 and expose a top surface of the patterned amorphous silicon layer 111.

Referring to FIG. 11 and FIG. 11A, a wet etching process is performed on the patterned amorphous silicon layer 111 by using tetramethylammonium hydroxide, while the oxide on the sidewall of the amorphous silicon layer 111 is retained, so that a first cavity 127 is formed to expose the top surface of the patterned oxide layer 110.

Referring to FIG. 12 and FIG. 12A, a reactive ion etching process is sequentially performed on the patterned oxide layer 110 and the plurality of stacked structures in the vertical direction and stops at a portion of the lower drain layer in the pull-up transistor device layer, so as to form a rectangular ring structure as a nanosheet and an inner cavity surrounded by the nanosheet. For example, the reactive ion etching process may stop at a middle of the first lower semiconductor layer, so that a second cavity (i.e., inner cavity) 128 including the first cavity 127 is formed in the active region.

Referring to FIG. 13 and FIG. 13A, a selective reactive ion etching process is performed on the SiGe material in the etched first intermediate semiconductor layer, the etched spacer semiconductor layer and the etched second intermediate semiconductor layer relative to the etched first lower semiconductor layer, the etched first upper semiconductor layer, the etched second lower semiconductor layer and the etched second upper semiconductor layer in the second cavity 128, so as to respectively form a lower lateral gap (lower inner lateral gap) 129 having a fifth width, an intermediate lateral gap (i.e., intermediate inner lateral gap) 130 having a sixth width, and an upper lateral gap (i.e., upper inner lateral gap) 131 having the fifth width, thereby exposing the lower channel layer 122, the remaining intermediate spacer 121 and the upper channel layer 123, respectively. The fifth width is greater than the sixth width.

In step S3903, the upper semiconductor layer and the lower semiconductor layer in the pull-down transistor device layer on the two long sides are respectively formed into an upper drain electrode and an upper source electrode. This step will be described in detail below.

Referring to FIG. 14 and FIG. 14A, an oxide is deposited on the shallow trench isolation and the second cavity 128, and then a planarization is performed to form an oxide layer 132 having a flat top surface. The upper inner lateral gap 131, the lower inner lateral gap 129 and the intermediate inner lateral gap 130 are filled with the oxide layer.

Referring to FIG. 15 and FIG. 15A, the oxide layer on the bottom surface of the pull-down transistor device is removed through an oxide recess process to form a third cavity 133, so that the exposed remaining second lower semiconductor layer, the exposed remaining second upper semiconductor layer and the exposed remaining intermediate spacer 121 sandwiched therebetween are respectively formed into an upper rectangular ring, a lower rectangular ring, and an intermediate rectangular ring sandwiched therebetween. An upper inner lateral gap 134 and an upper outer lateral gap 135 are respectively formed on both sides of the remaining intermediate spacer 121 sandwiched between the remaining second lower semiconductor layer and the remaining second upper semiconductor layer. A top surface of the shallow trench isolation is aligned with a bottom surface of the third cavity and the bottom surface of the pull-down transistor device.

Referring to FIG. 16 and FIG. 16A, oxide is deposited on opposite sidewalls of the pull-down transistor device, or oxide and silicon nitride are sequentially deposited on opposite sidewalls of the pull-down transistor device, so as to form an oxide layer and a silicon nitride layer in the upper inner lateral gap 134 and the upper outer lateral gap 135. Then, a selective etching process is performed on the oxide layer and the silicon nitride layer to form an upper inner spacer 136 in the upper inner lateral gap 134 and an upper outer spacer 137 in the upper outer lateral gap 135. The upper inner lateral gap 134, the upper outer lateral gap 135, the upper inner spacer 136 and the upper outer spacer 137 are all rectangular rings.

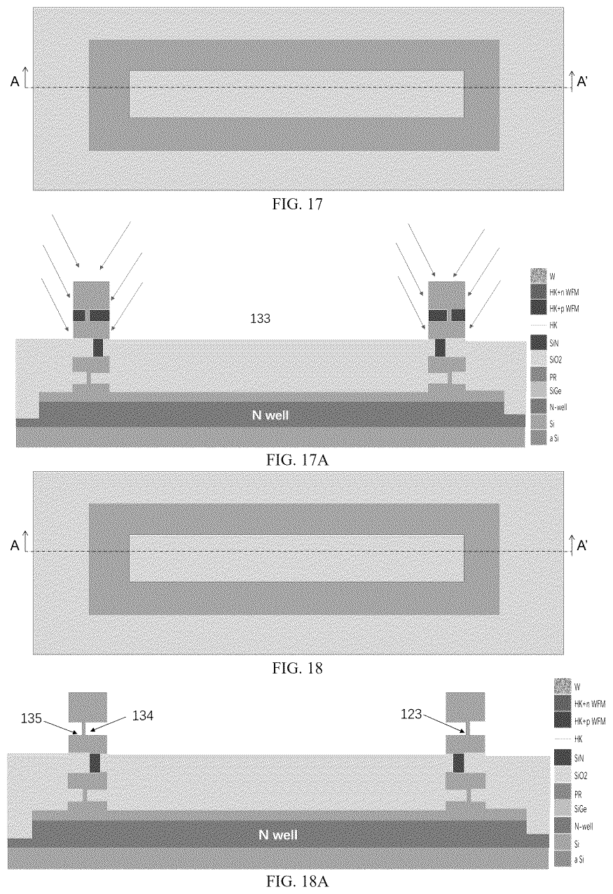

Referring to FIG. 17 and FIG. 17A, by using the ring-shaped upper inner spacer 136 and the ring-shaped upper outer spacer 137 as masks, an S/D implantation process is performed on the remaining second lower semiconductor layer and the remaining second upper semiconductor layer of the pull-down transistor device to respectively form an upper source electrode and an upper drain electrode of the pull-down transistor device layer.

In step S3904, two trenches as well as first protruding portions and second protruding portions that sandwich the trenches are formed in a centrally symmetrical manner on the two long sides of the rectangular ring structure. The two trenches pass through the upper drain layer and the upper channel layer in the pull-down transistor device layer, so as to separate a drain region and a channel region of the pull-down transistor from a drain region and a channel region of the pass gate transistor on each long side. This step will be described in detail below.

Referring to FIG. 18 and FIG. 18A, the silicon nitride layer in the upper inner spacer 136 and the upper outer spacer 137 is removed while the oxide layer therein is retained to restore the upper inner lateral gap 134 and the upper outer lateral gap 135, thereby exposing the upper channel layer 123.

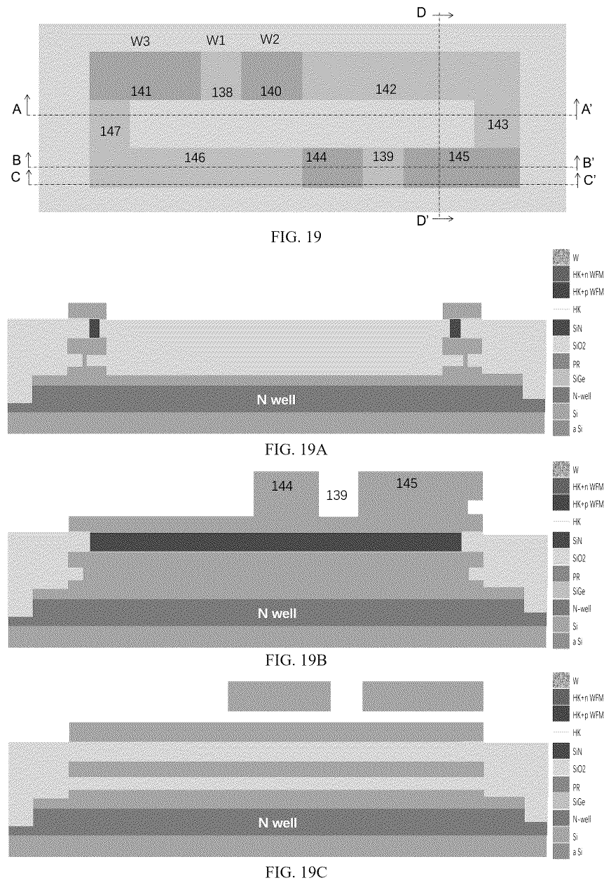

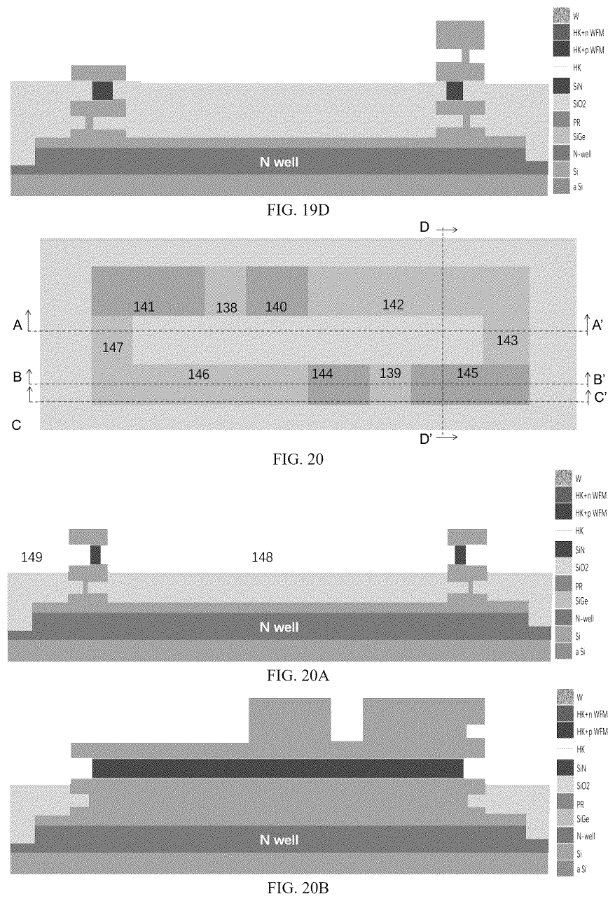

Referring to FIG. 19, FIG. 19A, FIG. 19B, FIG. 19C and FIG. 19D, a photolithography is performed on the drain electrode of the pull-down transistor device, followed by a fin cutting process. A center of the inner ring of the rectangular ring coincides with a center of the outer ring, to be used as a center of the rectangular ring. Specifically, the remaining second upper semiconductor layer and the upper channel layer 123 are removed from a first short side 143, a second short side 147, a right half 142 of the first long side and a left half 146 of the second long side of the rectangular ring (i.e., a portion of the first long side in a first quadrant and a portion of the second long side in a third quadrant in a plane coordinate system with the center of the rectangular ring as an origin) in a centrally symmetrical manner. Then, a fin cutting process is performed on a left half of the first long side and a right half of the second long side (i.e., a portion of the first long side in a second quadrant and a portion of the second long side in a fourth quadrant in the plane coordinate system with the center of the rectangular ring as the origin) to respectively form a first trench 138 having a width W1 and a second trench 139 having the width W1, where the first trench 138 divides the left half of the first long side into a first protruding portion 140 having a second width W2 and a second protruding portion 141 having a third width W3, and the second trench 139 divides the right half of the second long side into a first protruding portion 144 having the second width W2 and a second protruding portion 145 having the third width W3. The second upper semiconductor layer and the upper channel layer 123 left unetched are formed into the first protruding portion 140, the second protruding portion 141, the first protruding portion 144 and the second protruding portion 145.

In step S3905, a first step, a second step and a third step are formed at remaining portions on the two long sides. The first step exposes the lower semiconductor layer in the pull-down transistor device layer, the second step exposes a portion of the intermediate spacer as well as the upper semiconductor layer in the pull-up transistor device layer, and the third step exposes the lower semiconductor layer in the pull-up transistor device layer. The first step is adjacent to the first protruding portion.

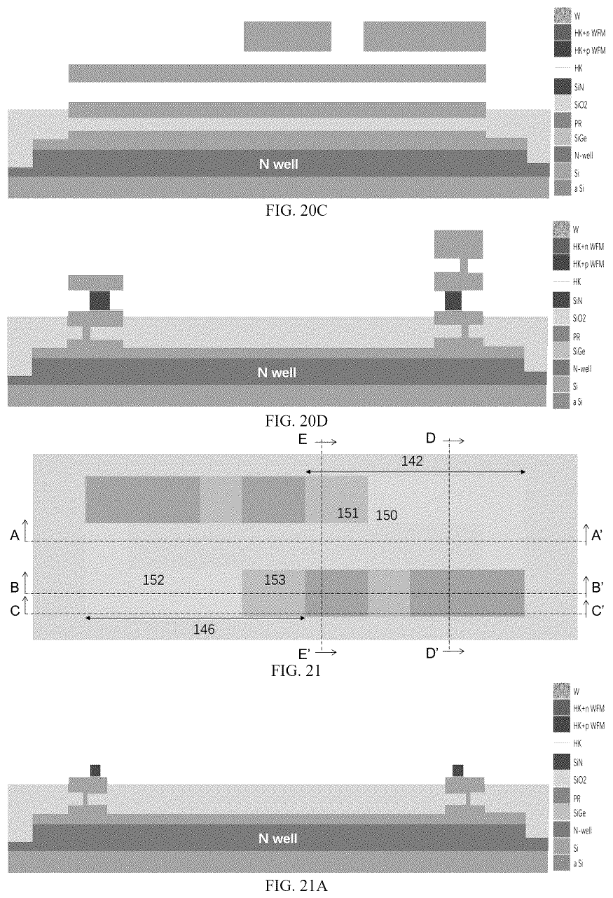

Referring to FIG. 20, FIG. 20A, FIG. 20B, FIG. 20C, FIG. 20D and FIG. 20E, an oxide recess process is further performed on the outer shallow trench isolation and the third cavity 133 until the top surface of the oxide layer is lower than the top surface of the first upper semiconductor layer (i.e., the source electrode) of the pull-up transistor device, so as to form a fourth cavity 148 inside the rectangular ring and a recessed portion 149 outside the rectangular ring. The remaining intermediate spacer 121 is exposed by the fourth cavity 148 and the recessed portion 149.

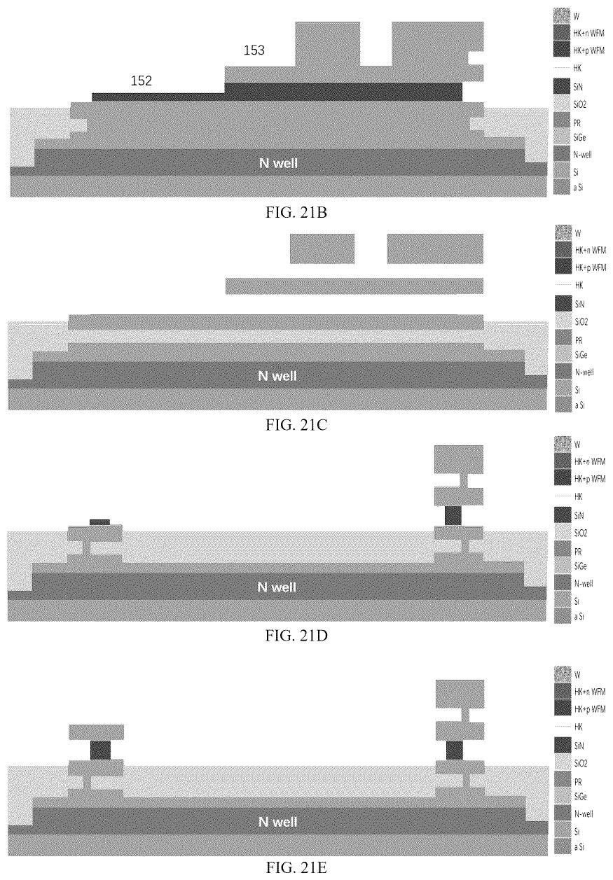

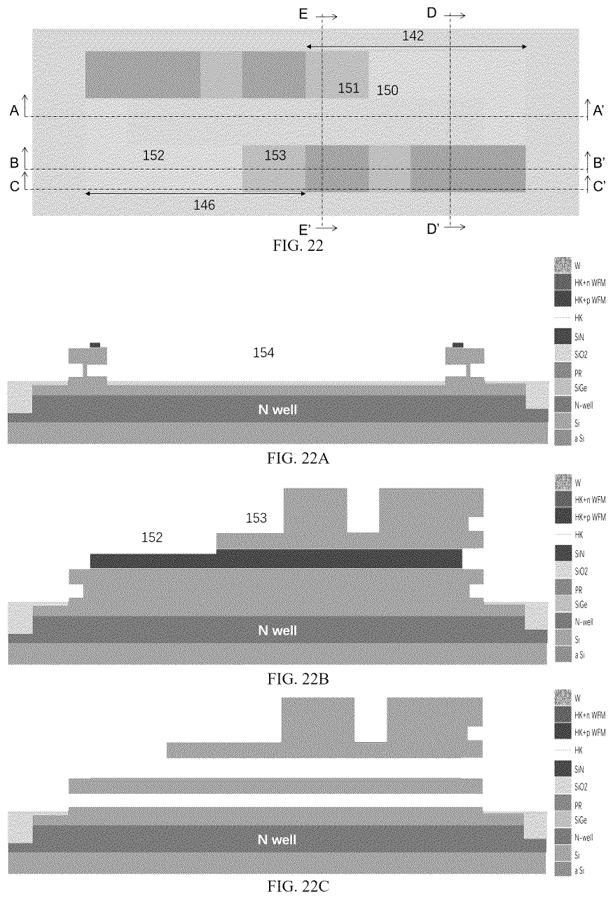

Referring to FIG. 21, FIG. 21A, FIG. 21B, FIG. 21C, FIG. 21D and FIG. 21E, a photolithography and a fin cutting process are performed on the second lower semiconductor layer and the remaining intermediate spacer 121 (the source electrode of the pull-down transistor device and the intermediate spacer between the pull-down transistor device and the pull-up transistor device) on the first short side 143, a first portion 150 on the right half 142 of the first long side, the second short side 147, and a first portion 152 on the left half 146 of the second long side, while the first step 151 having the width W2 on the right half 142 of the first long side and the first step 153 having the width W2 on the left half 146 of the second long side remain unetched. The first step 151 on the first long side and the first step 153 on the second long side have the same width as the first protruding portion 140 or 144 on the first long side or the second long side. The first step 151 (or 153) is adjacent to the first protruding portion 140 (or 144).

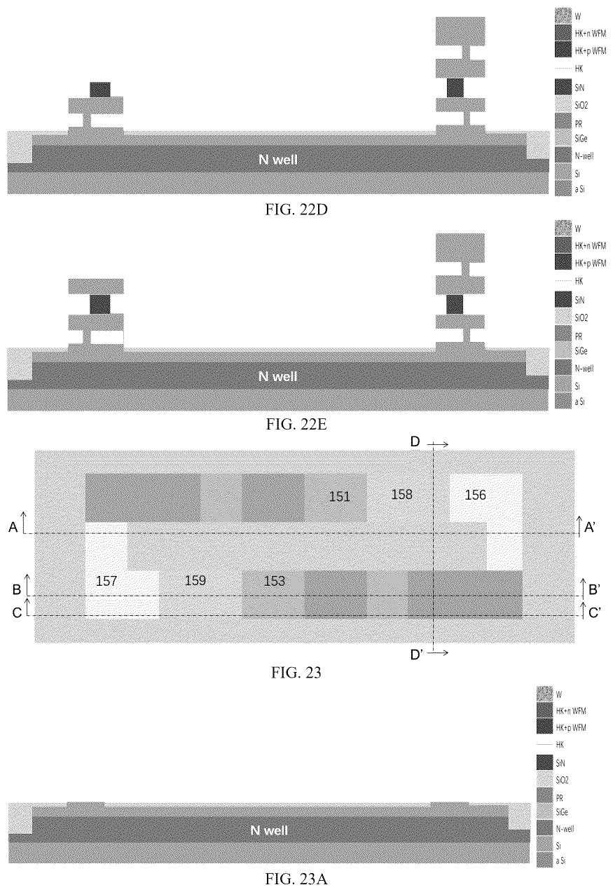

Referring to FIG. 22, FIG. 22A, FIG. 22B, FIG. 22C, FIG. 22D and FIG. 22E, an oxide recess process is performed on the fourth cavity 148 and the recessed portion 149 and stops at the first lower semiconductor layer of the pull-up transistor device, so as to form a fifth cavity 154 below the fourth cavity 148 and a recessed portion 155 below the recessed portion 149.

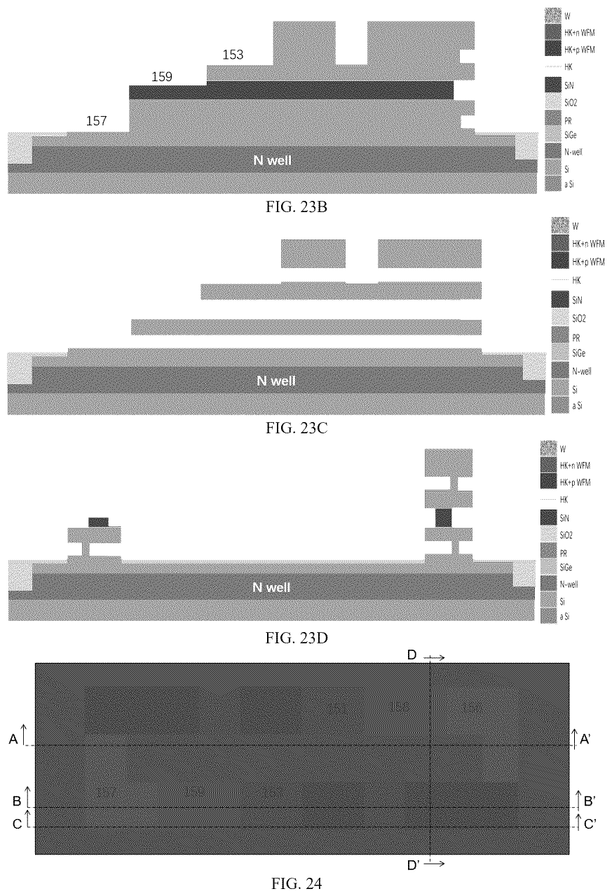

Referring to FIG. 23, FIG. 23A, FIG. 23B, FIG. 23C and FIG. 23D, a photolithography and a fin cutting process are performed on the first upper semiconductor layer and the first intermediate semiconductor layer (the source electrode and the channel of the pull-up transistor device) on the first short side 143, the third step 156 on the right half 142 of the first long side, the second short side 147, and the third step 157 on the left half 146 of the second long side, so as to expose the first lower semiconductor layer (i.e., the drain electrode of the pull-up transistor device). The second step 158 on the right half 142 of the first long side and the second step 159 on the left half 146 of the second long side remain exposing the remaining intermediate spacer 121 and the first upper semiconductor layer. Referring to FIG. 23B, the first long side after cutting includes a third step 156, a second step 158 and a first step 151 from bottom to top, and the second long side after cutting includes a third step 157, a second step 159 and a first step 153 from bottom to top.

In step S3906, metal gate electrodes of transistors are formed at inner end portions and outer end portions of the upper channel layer and the lower channel layer in the rectangular ring structure, and a first metal gate electrode and a second metal gate electrode are formed. The first metal gate electrode connects the second step on the first long side with the first protruding portion on the second long side, and the second metal gate electrode connects the first protruding portion on the first long side with the second step on the second long side.

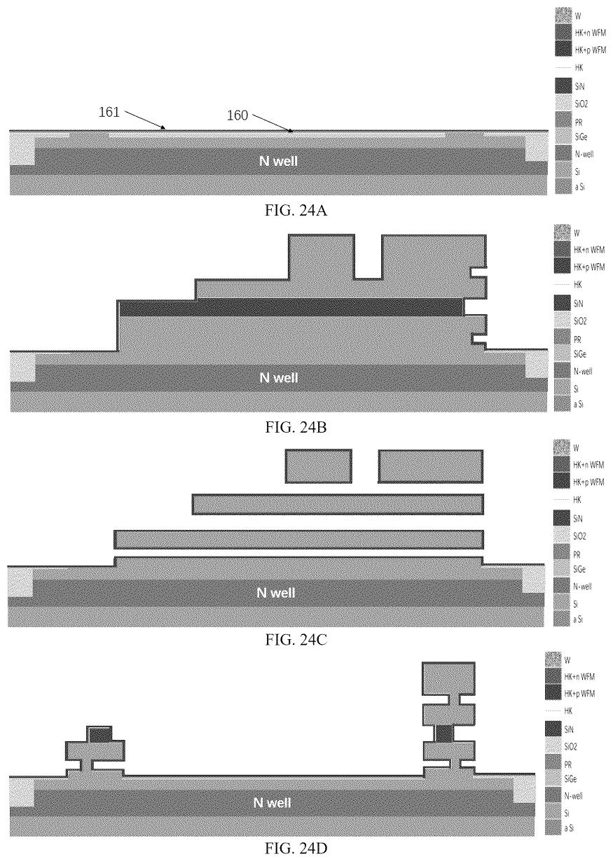

Referring to FIG. 24, FIG. 24A, FIG. 24B, FIG. 24C, FIG. 24D and FIG. 24E, a high-K dielectric layer (HK) and a p-type work function metal layer (p WFM) are conformally deposited on the wafer substrate. Specifically, a high-K dielectric layer (HK) 160 and a p-type work function metal layer (p WFM) 161 are conformally deposited on surfaces of the fifth cavity 154, the recessed portion 155, the third step 156, the second step 158, the first step 151, the third step 157, the second step 159, the first step 153, various gaps, the first trench 138, the second trench 139, the first protruding portion 140, the second protruding portion 141, the first protruding portion 144 and the second protruding portion 145.

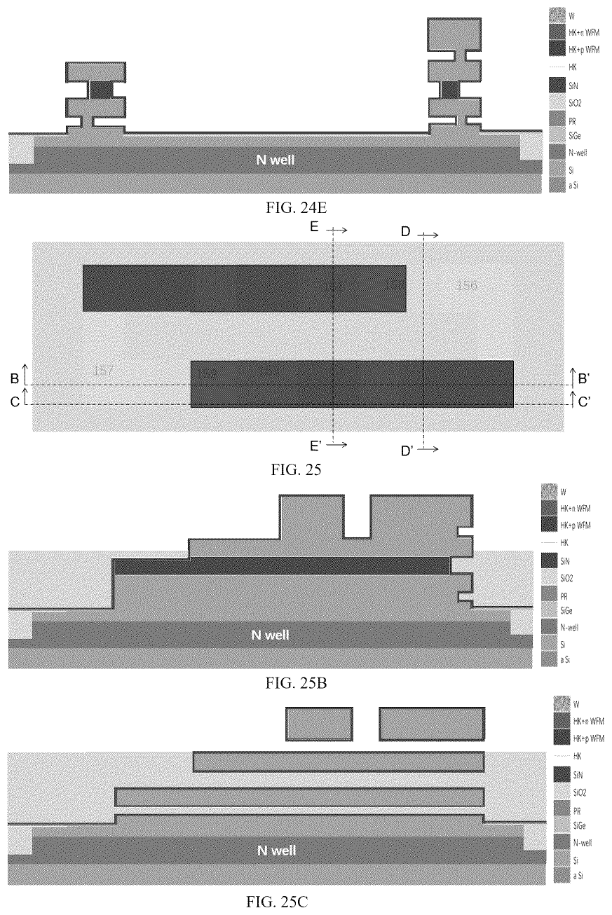

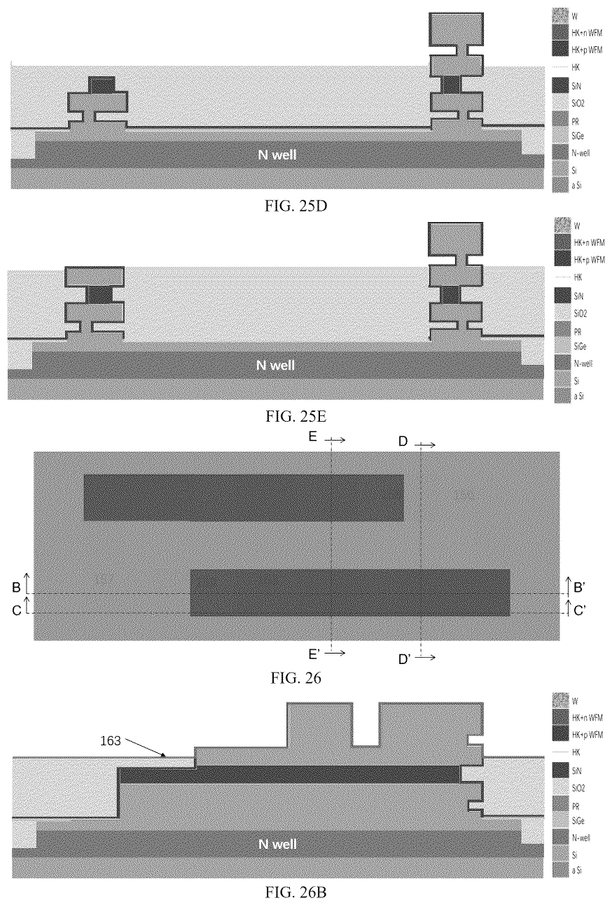

Referring to FIG. 25, FIG. 25B, FIG. 25C, FIG. 25D and FIG. 25E, an oxide layer 162 is deposited on the high-K dielectric layer (HK) and the p-type work function metal layer (p WFM), and a chemical mechanical polishing (CMP) process is performed on the oxide layer. Then, a recess process is performed on the oxide layer, so that a remaining oxide layer exposes the pull-down transistor device, that is, exposes the first protruding portion 140, the first trench 138, the second protruding portion 141 and the first step 151 on the first long side and exposes the first protruding portion 144, the second trench 139, the second protruding portion 145 and the first step 153 on the second long side.

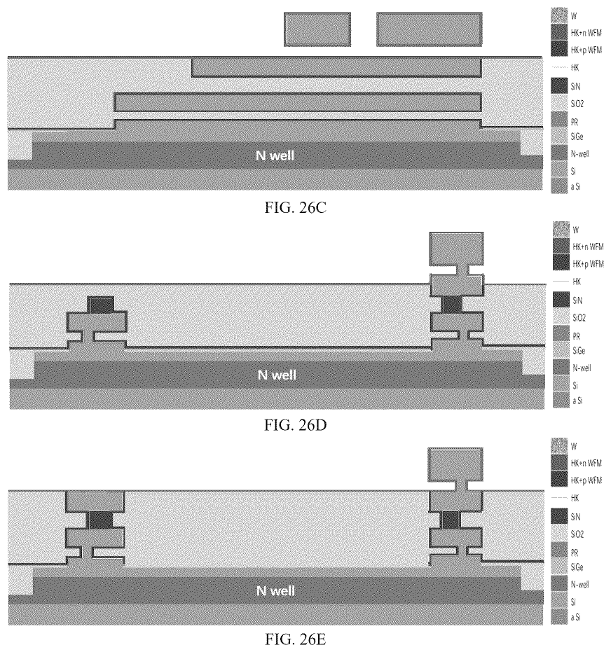

Referring to FIG. 26, FIG. 26B, FIG. 26C, FIG. 26D and FIG. 26E, the p-type work function metal layer on the first protruding portion 140, the first trench 138, the second protruding portion 141 and the first step 151 on the first long side and the first protruding portion 144, the second trench 139, the second protruding portion 145 and the first step 153 on the second long side is etched, and then an n-type work function metal layer (n WFM) 163 is conformally deposited on the entire wafer substrate.

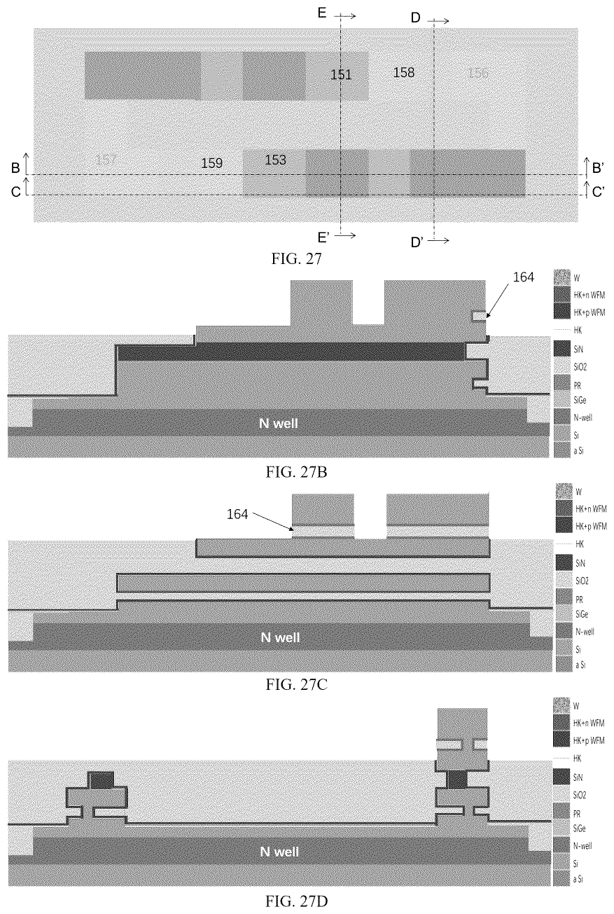

Referring to FIG. 27, FIG. 27B, FIG. 27C, FIG. 27D and FIG. 27E, an oxide layer is deposited on the n-type work function metal layer (n WFM) 163, and the oxide layer is etched to form an oxide spacer 164 in the upper inner lateral gap 134 and the upper outer lateral gap 135 at positions of the first protruding portion 140 and the second protruding portion 141 on the first long side and positions of the first protruding portion 144 and the second protruding portion 145 on the second long side.

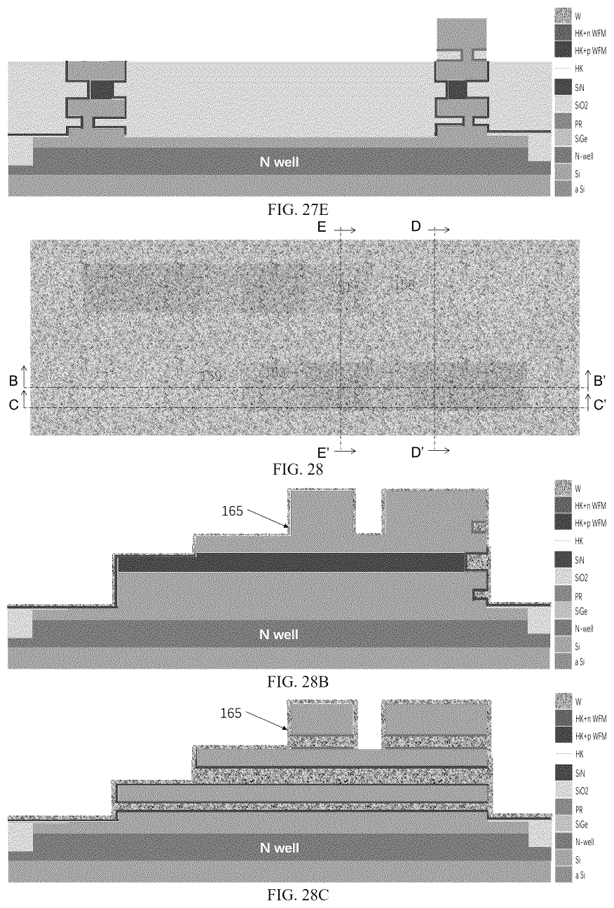

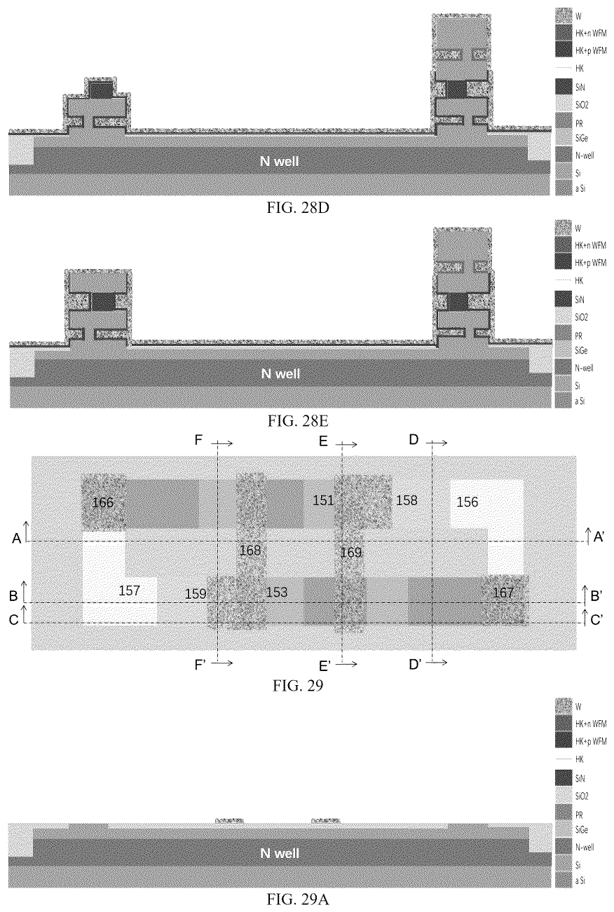

Referring to FIG. 28, FIG. 28B, FIG. 28C, FIG. 28D and FIG. 28E, a recess process is performed on the oxide layer and stops at the third step 156 on the right half of the first long side and the third step 157 on the left half of the second long side, while the p-type work function metal layer (p WFM) 161 and the n-type work function metal layer (n WFM) 163 remain unetched. Then, a tungsten metal layer 165 is conformally deposited on the wafer substrate.

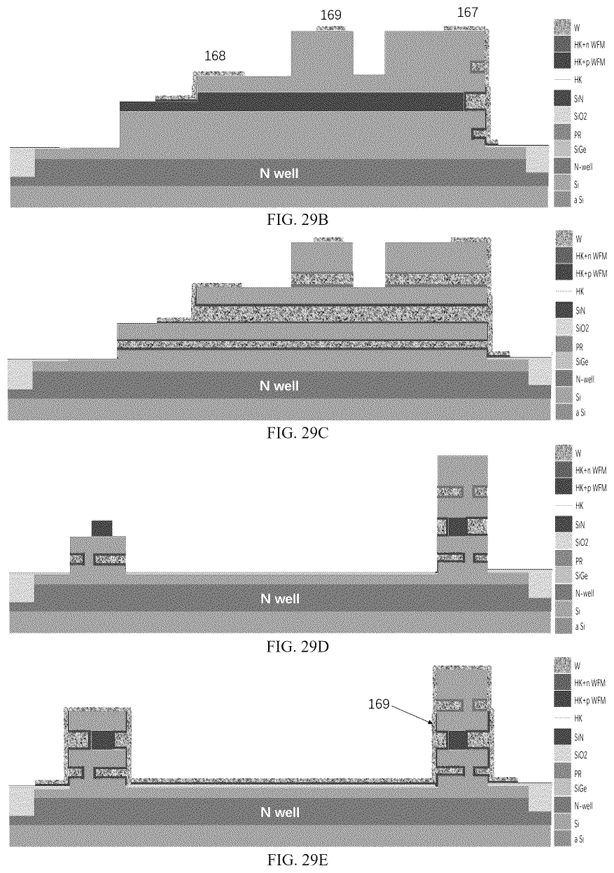

Referring to FIG. 29, FIG. 29A, FIG. 29B, FIG. 29C, FIG. 29D, FIG. 29E and FIG. 29F, a photolithography and an anisotropic etching process are performed on the tungsten metal layer 165 and the p-type work function metal layer (p WFM) 161 and stop at the high-K dielectric layer (HK). Specifically, the first high-K metal gate electrode 166 is formed into an upper metal gate electrode and a lower metal gate electrode in a gap at a left end portion of the second protruding portion 141 on the first long side, and the second high-K metal gate electrode 167 is formed into an upper metal gate electrode and a lower metal gate electrode in a gap at a right end portion of the second protruding portion on the second long side. The upper metal gate electrode and the lower metal gate electrode on the first long side include the high-K metal gate electrode in the upper inner lateral gap 134 and the upper outer lateral gap 135, so as to respectively form transistors PU1, PD1 and AX1 shown in FIG. 38, where the drain electrode and the gate electrode of the transistor PD1 are separated from the drain electrode and the gate electrode of the transistor AX1 by the first trench 138. The upper metal gate electrode and the lower metal gate electrode on the second long side include the high-K metal gate electrode in the upper inner lateral gap 134 and the upper outer lateral gap 135, so as to respectively form the transistors PU2, PD2 and AX2 shown in FIG. 38, where the drain electrode and the gate electrode of the transistor PD2 are separated from the drain electrode and the gate electrode of the transistor AX2 by the second trench 139. A third high-K metal gate electrode 168 connects the first step 151 on the first long side with the first protruding portion 144 on the second long side and extends continuously from the first step 151 to the second step 158 on the first long side. A fourth high-K metal gate electrode 169 connects the first protruding portion 140 on the first long side with the first step 153 on the second long side and extends continuously from the first step 153 to the second step 159 on the second long side.

In step S3907, a plurality of contacts are formed on the rectangular ring structure to respectively connect to the third step, the first protruding portion, the second protruding portion, and the metal gate electrode of the pass gate transistor.

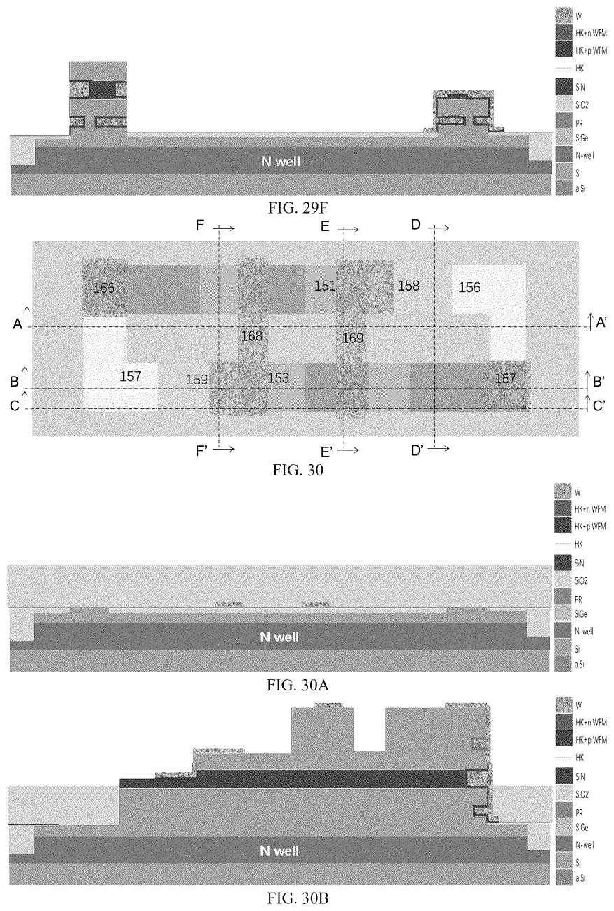

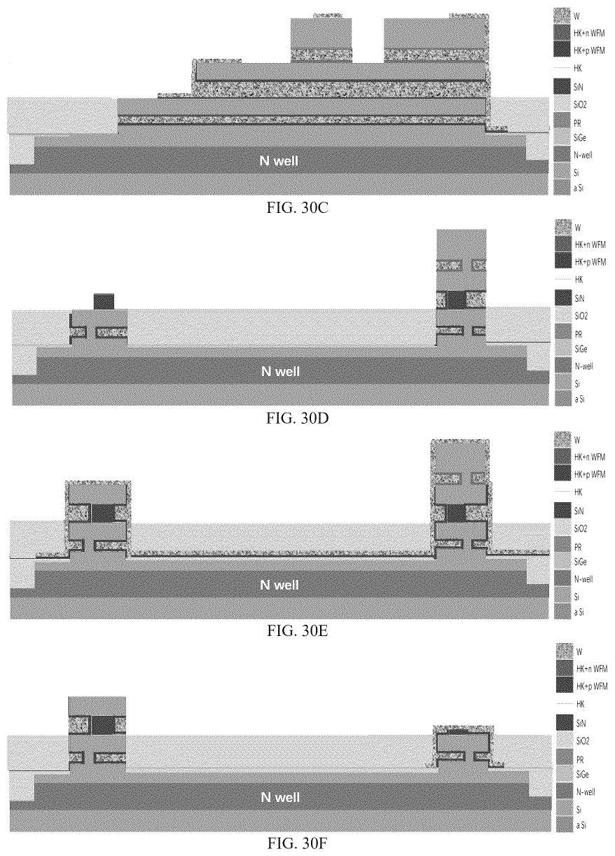

Referring to FIG. 30, FIG. 30A, FIG. 30B, FIG. 30C, FIG. 30D, FIG. 30E and FIG. 30F, an oxide layer is deposited on the wafer substrate and a chemical mechanical polishing process is performed on the oxide layer. A recess process is performed on the oxide layer after the chemical mechanical polishing and stops at the source electrode of the pull-up transistor device.

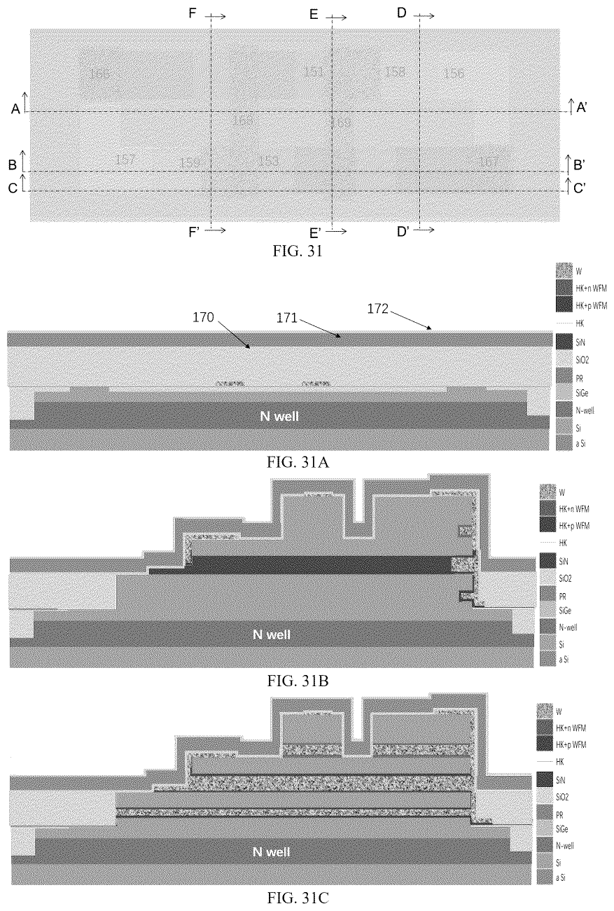

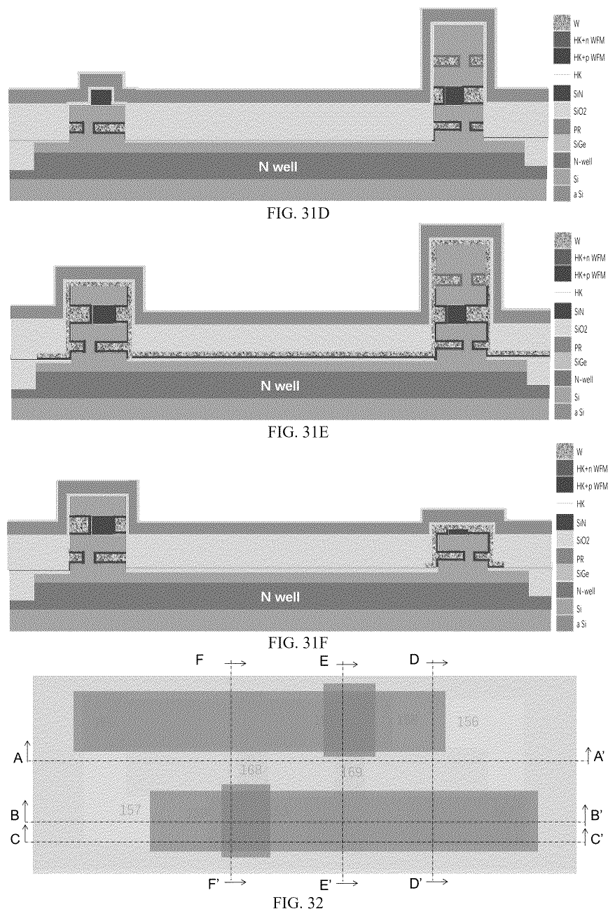

Referring to FIG. 31, FIG. 31A, FIG. 31B, FIG. 31C, FIG. 31D, FIG. 31E and FIG. 31F, a bottom oxide layer 170, an intermediate amorphous silicon layer 171 and a top oxide layer 172 are sequentially deposited on the wafer substrate.

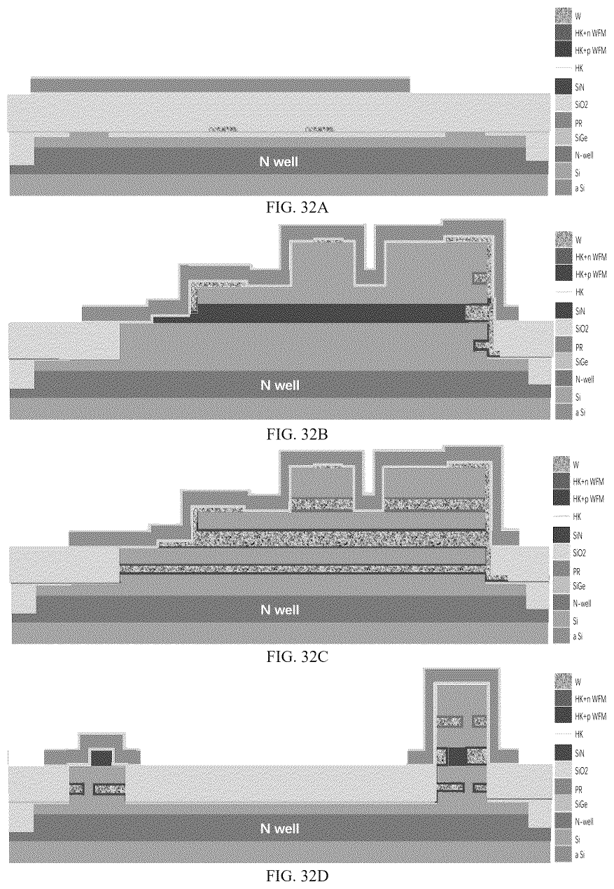

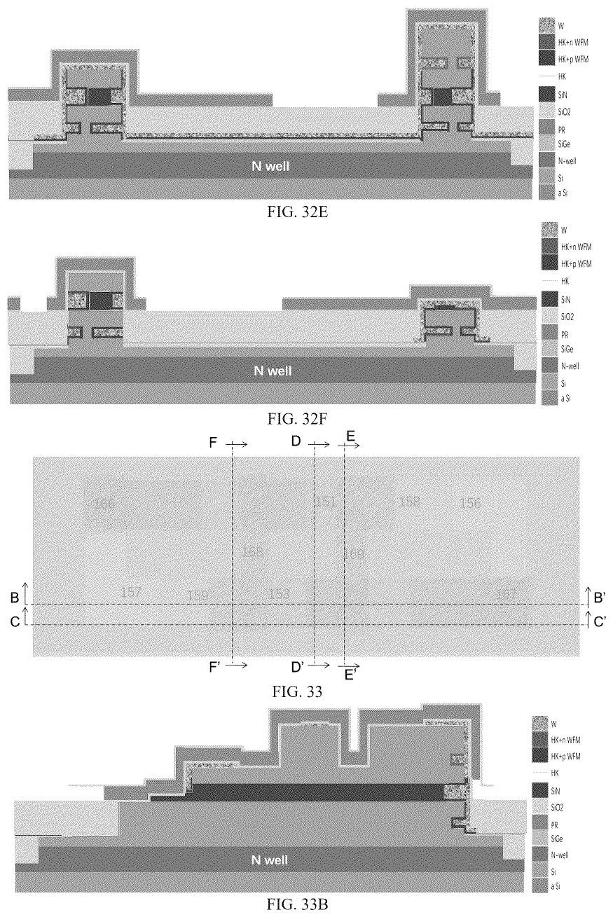

Referring to FIG. 32, FIG. 32A, FIG. 32B, FIG. 32C, FIG. 32D, FIG. 32E and FIG. 32F, a photolithography and an etching process are performed on the top oxide layer 172 and the intermediate amorphous silicon layer 171 among the bottom oxide layer 170, the intermediate amorphous silicon layer 171 and the top oxide layer 172. Specifically, the bottom oxide layer 170, the intermediate amorphous silicon layer 171 and the top oxide layer 172 except for those on the first short side 143, the second short side 147, a portion of the third step on the right half of the first long side and a portion of the third step on the left half of the second long side remain unremoved.

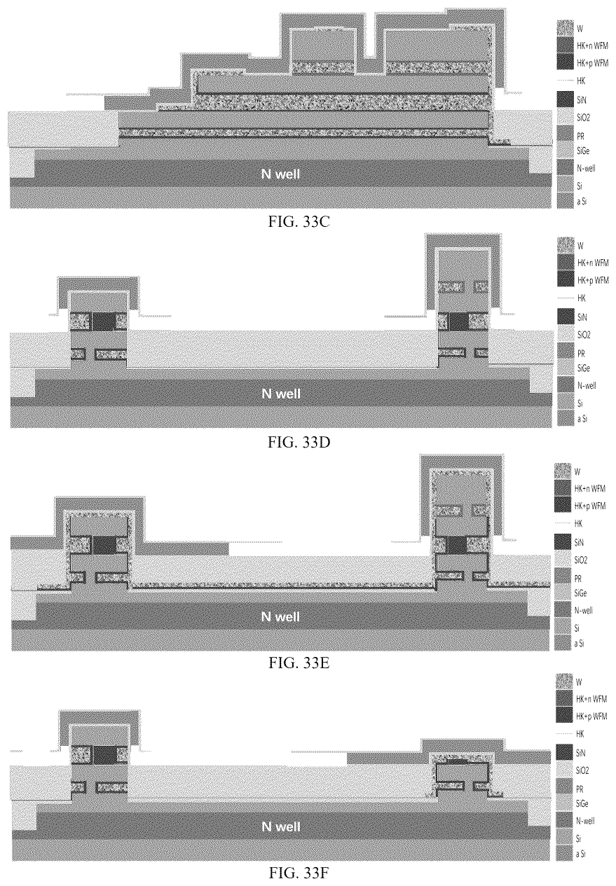

Referring to FIG. 33, FIG. 33B, FIG. 33C, FIG. 33D, FIG. 33E and FIG. 33F, the intermediate amorphous silicon layer 171 on the first long side and the second long side is etched using tetramethylammonium hydroxide (TMAH), so that the exposed intermediate amorphous silicon layer 171 is recessed.

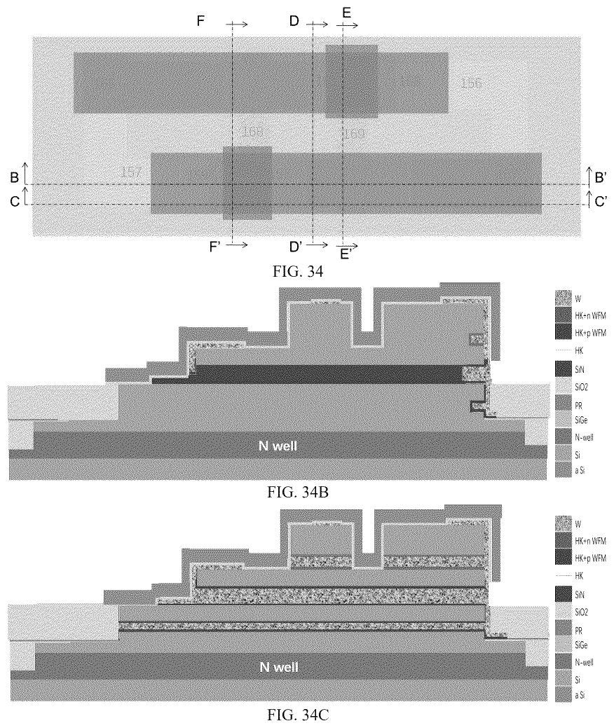

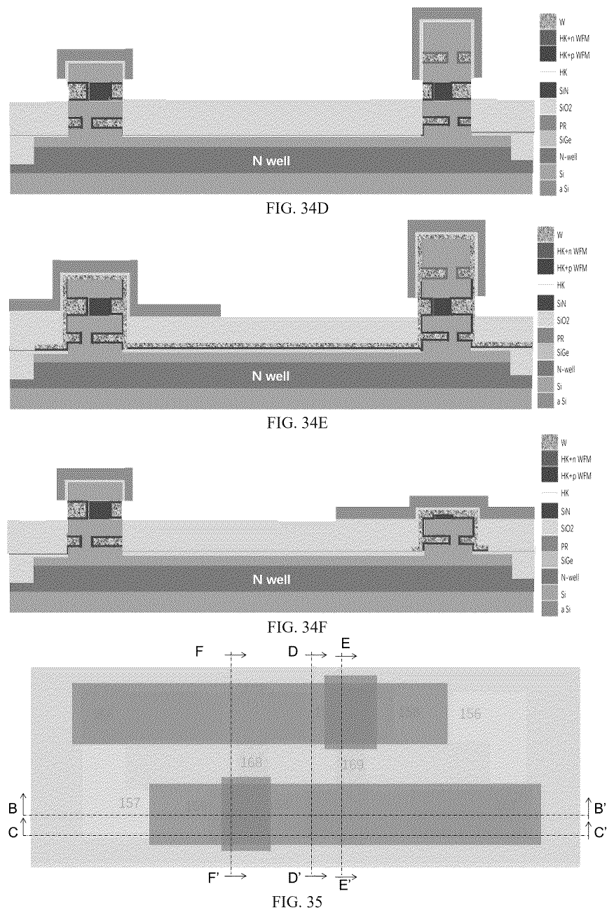

Referring to FIG. 34, FIG. 34B, FIG. 34C, FIG. 34D, FIG. 34E and FIG. 34F, the top oxide layer 172 on the first long side and the second long side is etched using hydrofluoric acid solution to expose the remaining intermediate amorphous silicon layer.

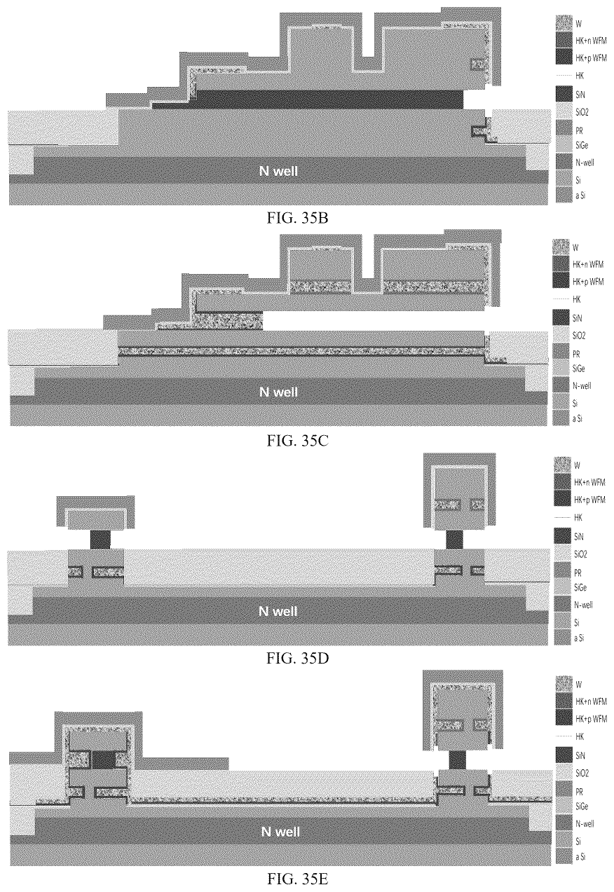

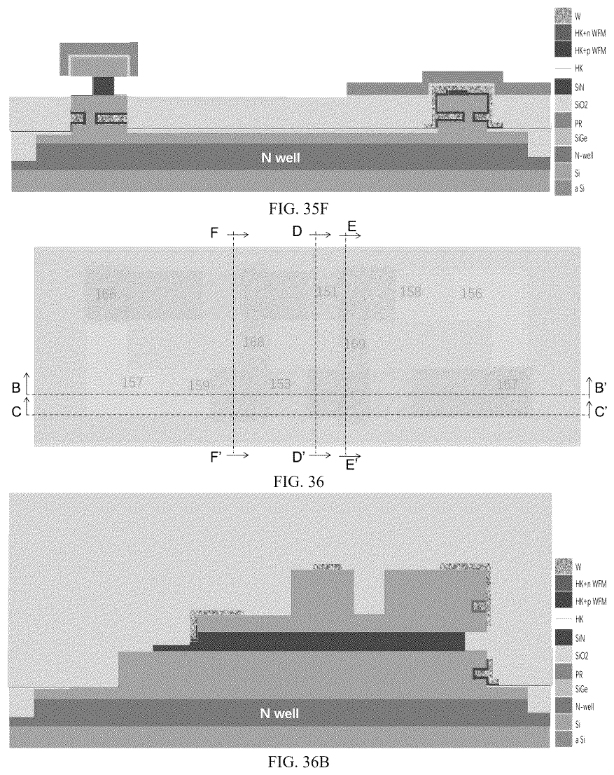

Referring to FIG. 35, FIG. 35B, FIG. 35C, FIG. 35D, FIG. 35E and FIG. 35F, by using the remaining intermediate amorphous silicon layer and the corresponding bottom oxide layer as masks, an anisotropic etching process is performed on the exposed first high-K metal gate electrode 166, the exposed second high-K metal gate electrode 167, the exposed third high-K metal gate electrode 168 and the exposed fourth high-K metal gate electrode 169, so that the gate electrodes of the transistors PD1, PU1 and AX1 are separated and the gate electrodes of the transistors PU2, PD2 and AX2 are separated.

Referring to FIG. 36, FIG. 36B, FIG. 36C, FIG. 36D, FIG. 36E and FIG. 36F, the remaining intermediate amorphous silicon layer 171 is removed, then an oxide layer 173 is deposited on the wafer substrate, and a chemical mechanical polishing process is performed on the oxide layer 173.

Referring to FIG. 37 and FIG. 37B, a plurality of holes are formed in the polished oxide layer 173, and the holes are filled with a metal material to form a plurality of contacts. The plurality of contacts include two word line contacts WL respectively connected to the third high-K metal gate electrode 168 and the fourth high-K metal gate electrode 169, bit line contacts BL and BLB respectively connected to the pass gate transistors AX1 and AX2, two power contacts VSS respectively connected to the drain electrodes of the transistors PD1 and PD2, and power contacts VDD respectively connected to the drain electrodes of the transistors PU1 and PU2.

Another specific embodiment of the present disclosure provides a memory, including a plurality of vertical channel SRAM cells arranged in rows and columns. The vertical channel SRAM cells are manufactured using the method of manufacturing the vertical channel SRAM cell described in the above embodiments.

Another specific embodiment of the present disclosure provides an electronic device provided with the memory described in the above embodiments. For example, the electronic device includes a computer, a server, a mobile phone, a PAD, etc.

Compared with the related art, the present disclosure may achieve at least one of the following beneficial effects.
1. The vertical channel SRAM cell includes vertically structured gate-all-around field-effect-transistors, and a structure of each memory cell has a compact layout by forming a pull-up transistor in the pull-up transistor layer and forming a pull-down transistor and a pass gate transistor in the pull-down transistor layer on each side of the rectangular ring.
2. The overall manufacturing process facilitates the production of vertical channel SRAM cell.

Those skilled in the art may understand that all or part of processes for implementing the method of the above embodiments may be performed by instructing relevant hardware through a computer program, and the program may be stored in a computer-readable storage medium. The computer-readable storage medium is a magnetic disk, an optical disk, a read only memory, a random access memory, etc.

The above are merely preferred specific embodiments of the present disclosure, and the scope of protection of the present disclosure is not limited to this. Any changes or substitutions that may be easily conceived by those skilled in the art within the scope of the technology disclosed in the present disclosure should be contained in the scope of protection of the present disclosure.

What is claimed is:

1. A vertical channel SRAM cell, comprising:
a pull-up transistor device layer comprising a pull-up transistor;
an intermediate spacer layer on the pull-up transistor device layer; and
a pull-down transistor device layer separated from the pull-up transistor device layer by the intermediate spacer layer, wherein the pull-down transistor device layer comprises a pull-down transistor and a pass gate transistor, the pull-up transistor comprises a first pull-up transistor and a second pull-up transistor, the pull-down transistor comprises a first pull-down transistor and a second pull-down transistor, and the pass gate transistor comprises a first pass gate transistor and a second pass gate transistor;
wherein the pass gate transistor is connected with the pull-down transistor by an upper source layer at identical height; and
wherein the first pull-up transistor and the first pull-down transistor form a first inverter, the second pull-up transistor and the second pull-down transistor form a second inverter, and the first inverter and the second inverter are coupled to each other through a metal gate strip.

2. The vertical channel SRAM cell according to claim 1, further comprising:
a wafer substrate;
an N well on the wafer substrate;
a rectangular ring structure comprising a plurality of stacked structures on the N well, wherein a first long side of the rectangular ring comprises the first pull-up transistor, the first pull-down transistor and the first pass gate transistor, and a second long side of the rectangular ring comprises the second pull-up transistor, the second pull-down transistor and the second pass gate transistor;
an insulation layer, located on the rectangular ring structure and an inner cavity of the rectangular ring structure, wherein the pull-up transistor device layer comprises a lower drain layer, a lower channel layer on the lower drain layer, a lower metal gate electrode horizontally surrounding the lower channel layer, and a lower source layer on the lower channel layer and the lower metal gate electrode; the pull-down transistor device layer comprises the upper source layer on the intermediate spacer layer, an upper channel layer on the upper source layer, an upper metal gate electrode horizontally surrounding the upper channel layer, and an upper drain layer on the upper channel layer and the upper metal gate electrode; and the intermediate spacer layer is located between the lower source layer and the upper source layer; and
a trench passing through the upper drain layer, the upper channel layer and the upper metal gate electrode to expose a top surface of the upper source layer, so as to separate a drain electrode, a channel and a metal gate electrode of the pull-down transistor from a drain electrode, a channel and a metal gate electrode of the pass gate transistor;
wherein the lower drain layers of the pull-up transistors on the two long sides are connected by short sides of the rectangular ring.

3. The vertical channel SRAM cell according to claim 2, wherein a structure on the first long side is central symmetrical to a structure on the second long side with respect to a center of gravity of the rectangular ring, and the first long side and the second long side are both divided into a first portion and a second portion having the same length;
wherein the first portion comprises a first step exposing the upper source layer, a second step exposing the lower source layer and a portion of the intermediate spacer layer, and a third step exposing the lower drain layer; a metal gate connector is located on a partial top surface of the first step, a partial top surface of the second step, and a sidewall between the first step and the second step, so that the upper source layer and the lower source layer are connected through the metal gate connector; and
wherein the second portion comprises the trench as well as a first protruding portion and a second protruding portion that sandwich the trench, and the first protruding portion is adjacent to the first step.

4. The vertical channel SRAM cell according to claim 3, wherein the metal gate strip comprises a first metal gate strip and a second metal gate strip, and the vertical channel SRAM cell further comprises:
a first power contact passing through the insulation layer to reach a top surface of the third step;
a second power contact passing through the insulation layer to reach a top surface of the first protruding portion;
a bit line contact passing through the insulation layer to reach a top surface of the second protruding portion;
a word line contact passing through the insulation layer to reach the upper metal gate electrode on the top surface of the second protruding portion;
the first metal gate strip configured to connect the second step on the first long side with the first protruding portion on the second long side; and
the second metal gate strip configured to connect the first protruding portion on the first long side with the second step on the second long side.

5. A method of manufacturing a vertical channel SRAM cell, comprising:
forming an N well on a wafer substrate;
forming a plurality of stacked structures on the N well, and forming the plurality of stacked structures into a rectangular ring structure, wherein the plurality of stacked structures comprise a pull-up transistor device layer, an intermediate spacer and a pull-down transistor device layer from bottom to top, and the pull-up transistor device layer and the pull-down transistor device layer both comprise a lower semiconductor layer, a channel layer on the lower semiconductor layer, and an upper semiconductor layer on the channel layer;
forming the upper semiconductor layer and the lower semiconductor layer in the pull-down transistor device layer on two long sides of the rectangular ring structure into an upper drain electrode and an upper source electrode respectively;
forming two trenches as well as first protruding portions and second protruding portions that sandwich the two trenches on the two long sides of the rectangular ring structure in a centrally symmetrical manner, wherein the two trenches pass through an upper drain layer and an upper channel layer in the pull-down transistor device layer to separate a drain region and a channel region of a pull-down transistor from a drain region and a channel region of a pass gate transistor on each long side;
forming a first step, a second step and a third step at a remaining portion of the two long sides, wherein the first step exposes the lower semiconductor layer in the pull-down transistor device layer, the second step exposes the upper semiconductor layer in the pull-up transistor device layer and a portion of the intermediate spacer, the third step exposes the lower semiconductor layer in the pull-up transistor device layer, and the first step is adjacent to the first protruding portion;
forming metal gate electrodes of transistors at an inner end portion and an outer end portion of the upper channel layer and an inner end portion and an outer end portion of the lower channel layer in the rectangular ring structure, and forming a first metal gate electrode and a second metal gate electrode, wherein the first metal gate electrode connects the second step on the first long side with the first protruding portion on the second long side, and the second metal gate electrode connects the first protruding portion on the first long side with the second step on the second long side; and
forming a plurality of contacts on the rectangular ring structure to connect to the third step, the first protruding portion, the second protruding portion, and the metal gate electrode of the pass gate transistor, respectively.

6. The method of manufacturing the vertical channel SRAM cell according to claim 5, wherein the forming a plurality of stacked structures on the N well comprises:
forming a pull-up transistor device layer on the N well;
forming a spacer semiconductor layer on the pull-up transistor device layer; and
forming a pull-down transistor device layer on the spacer semiconductor layer, wherein the pull-up transistor device layer and the pull-down transistor device layer both comprise a lower semiconductor layer, an intermediate semiconductor layer on the lower semiconductor layer, and an upper semiconductor layer on the intermediate semiconductor layer,
wherein the lower semiconductor layer and the upper semiconductor layer of the pull-down transistor device layer are respectively an upper source layer and an upper drain layer, the lower semiconductor layer and the upper semiconductor layer of the pull-up transistor device layer are respectively a lower drain layer and a lower source layer, and the upper source layer, the upper drain layer, the lower drain layer and the lower source layer are made of silicon; and
wherein the intermediate semiconductor layer of the pull-down transistor device layer is a top intermediate semiconductor layer, the intermediate semiconductor layer of the pull-up transistor device layer is a bottom intermediate semiconductor layer, and the top intermediate semiconductor layer, the bottom intermediate semiconductor layer and the spacer semiconductor layer are made of germanium silicon.

7. The method of manufacturing the vertical channel SRAM cell according to claim 6, wherein the forming the plurality of stacked structures into a rectangular ring structure comprises:
forming a first oxide layer, an amorphous silicon layer and a second oxide layer sequentially on the upper drain layer in the pull-down transistor device layer;
performing a reactive ion etching process on the second oxide layer, the amorphous silicon layer and the first oxide layer by using a patterned photoresist layer as a mask, wherein the patterned photoresist layer has the same size as an inner ring of the rectangular ring structure in a vertical direction;
conformally depositing a third oxide layer on the upper drain layer and the etched second oxide layer;
performing a reactive ion etching process on the third oxide layer to form a spacer on an outer wall of the second oxide layer, an outer wall of the amorphous silicon layer and an outer wall of the first oxide layer;
etching the plurality of stacked structures into an outer rectangle of the rectangular ring by using the spacer as a mask, and stopping at a portion of the lower drain layer in the pull-up transistor device layer, so as to form an upper outer lateral gap having a first width at an outer end portion of the top intermediate semiconductor layer, a lower outer lateral gap having the first width at an outer end portion of the bottom intermediate semiconductor layer, and an intermediate outer lateral gap having a second width at an outer end portion of the spacer semiconductor layer, wherein the second width is greater than the first width;
forming an intermediate spacer having a third width in the intermediate outer lateral gap, and forming the upper channel layer having a fourth width in the upper outer lateral gap and the lower channel layer having the fourth width in the lower outer lateral gap to maintain a remaining upper outer lateral gap and a remaining lower outer lateral gap, wherein the third width is less than the second width, and the fourth width is less than the first width;
performing a chemical mechanical polishing process on the second oxide layer, and stopping at the amorphous silicon layer;
performing a wet etching process on the exposed amorphous silicon layer, continuing to perform a reactive ion etching process on the plurality of stacked structures and stopping at a portion of the lower drain layer in the pull-up transistor device layer, so as to form the rectangular ring structure as a nanosheet and an inner cavity surrounded by the nanosheet; and
performing a selective reactive ion etching process on the upper channel layer, the spacer semiconductor layer and the lower channel layer in the inner cavity relative to the upper drain layer, the upper source layer, the lower source layer and the lower drain layer, so as to form an upper inner lateral gap having a fifth width at the inner end portion of the upper channel layer, a lower inner lateral gap having the fifth width at the inner end portion of the lower channel layer, and an intermediate inner lateral gap having a sixth width at the inner end portion of the spacer semiconductor layer, wherein the fifth width is greater than the sixth width.

8. The method of manufacturing the vertical channel SRAM cell according to claim 7, wherein the forming the upper semiconductor layer and the lower semiconductor layer in the pull-down transistor device layer on two long sides of the rectangular ring structure into an upper drain electrode and an upper source electrode respectively comprises:
depositing a fourth oxide layer in the inner cavity, wherein the upper inner lateral gap, the lower inner lateral gap and the intermediate inner lateral gap are filled with the fourth oxide layer;
performing a recess process on a shallow trench isolation oxide and the fourth oxide layer and stopping at a bottom surface of the upper source layer, so as to restore the remaining upper outer lateral gap and the remaining upper inner lateral gap;
conformally depositing a fifth oxide layer and a silicon nitride layer in the remaining upper outer lateral gap and the remaining upper inner lateral gap, and performing a selective etching process on the fifth oxide layer and the silicon nitride layer to form an upper outer spacer and an upper inner spacer; and
performing a drain/source implantation process on the upper drain layer and the upper source layer by using the upper outer spacer and the upper inner spacer as masks, so as to form a drain/source implanted upper drain layer and a drain/source implanted upper source layer respectively.

9. The method of manufacturing the vertical channel SRAM cell according to claim 8, wherein the forming two trenches as well as first protruding portions and second protruding portions that sandwich the two trenches on the two long sides of the rectangular ring structure in a centrally symmetrical manner comprises:
removing the upper outer spacer and the upper inner spacer to restore the remaining upper outer lateral gap and the upper inner lateral gap to expose the upper channel layer; and
performing a photolithography and a fin etching process on the drain/source implanted rectangular ring structure, so as to remove the drain/source implanted upper drain layer and the upper channel layer on the two short sides, a right half of the first long side and a left half of the second long side, and form a first trench and a second trench on a left half of the first long side and a right half of the second long side respectively,
wherein the first trench and the second trench respectively expose a top surface of the upper source layer on the first long side and a top surface of the upper source layer on the second long side;
wherein the first trench is sandwiched between the first protruding portion and the second protruding portion on the first long side, and the second trench is sandwiched between the first protruding portion and the second protruding portion on the second long side; and
wherein the first trench has the same width as the second trench, the first protruding portion on the first long side has the same width as the first protruding portion on the second long side, and the second protruding portion on the first long side has the same width as the second protruding portion on the second long side.

10. The method of manufacturing the vertical channel SRAM cell according to claim 9, wherein the forming a first step, a second step and a third step at a remaining portion of the two long sides comprises:
continuing to perform a recess process on the shallow trench isolation oxide and the fifth oxide layer until reaching the lower source layer in the pull-up transistor device layer, so as to restore the intermediate outer lateral gap having the third width and the intermediate inner lateral gap;
performing a photolithography and a fin etching process on the two short sides, the first portion in the right half of the first long side and the first portion in the left half of the second long side, while leaving the first step on the first long side and the first step on the second long side unetched, wherein the first step on the first long side and the first step on the second long side have the same width as the first protruding portion;
continuing to perform a recess process on the shallow trench isolation oxide and the fifth oxide layer until reaching the lower drain layer in the pull-up transistor device layer, so as to restore the remaining lower outer lateral gap and the lower inner lateral gap to expose the lower channel layer; and
performing a photolithography and a fin etching process on the two short sides, a portion of the first portion on the first long side and a portion of the first portion on the second long side, so as to form the third step on the first long side and the third step on the second long side and leave the second step on the first long side and the second step on the second long side unetched.

11. The method of manufacturing the vertical channel SRAM cell according to claim 10, wherein the forming metal gate electrodes of transistors at an inner end portion and an outer end portion of the upper channel layer and an inner end portion and an outer end portion of the lower channel layer in the rectangular ring structure further comprises:
conformally depositing a high-K dielectric layer and a p-type work function metal layer on the wafer substrate;
depositing a sixth oxide layer on the p-type work function metal layer and performing a chemical mechanical polishing process on the sixth oxide layer;
performing a recess process on the sixth oxide layer to expose the pull-down transistor device layer;
etching the exposed p-type work function metal layer, and depositing an n-type work function metal layer on the exposed high-K dielectric layer;
depositing a seventh oxide layer on the n-type work function metal layer, and etching a portion of the seventh oxide layer and a portion of the n-type work function metal layer to form oxide spacers in the upper inner lateral gap and the lower inner lateral gap;
performing a recess process on the remaining oxide layer until reaching the p-type work function metal layer, and then depositing a tungsten metal layer; and
performing a photolithography and an anisotropic etching process on the tungsten metal layer and the p-type work function metal layer until reaching the high-K dielectric layer, so as to form metal gate electrodes of the pull-down transistor and the pass gate transistor at the inner end portion and the outer end portion of the upper channel layer and form a metal gate electrode of the pull-up transistor at the inner end portion and the outer end portion of the lower channel layer.

12. A memory comprising a plurality of vertical channel SRAM cells arranged in rows and columns, wherein the vertical channel SRAM cells are manufactured using the method of manufacturing the vertical channel SRAM cell of claim 5.

13. An electronic device provided with the memory of claim 12.
